(19) United States
(12) Patent Application Publication
(10) Pub. No.: US 2026/0239551 A1
(43) Pub. Date: Aug. 13, 2026

(54) LAMINATE AND IMAGE DISPLAY DEVICE

(71) Applicant: DAICEL CORPORATION, Osaka-shi, Osaka (JP)

(72) Inventors: Masashi YOKOYAMA, Tokyo (JP); Yusaku SAINOHIRA, Tokyo (JP)

(73) Assignee: DAICEL CORPORATION, Osaka-shi, Osaka (JP)

(21) Appl. No.: 19/150,412

(22) PCT Filed: Dec. 13, 2023
(86) PCT No.: PCT/JP2023/044731

§ 371 Date: Jul. 23, 2025

(30) Foreign Application Priority Data
Jan. 26, 2023 (JP) 2023-010550

(51) Int. Cl. H05K 5/03

(52) U.S. Cl. CPC H05K 5/03

(57) ABSTRACT

To provide a laminate having excellent surface hardness, impact resistance, and bending resistance. The laminate of the present disclosure is a laminate including a glass substrate and a hard coat layer laminated on at least one surface of the glass substrate, wherein the glass substrate has a thickness of from 1 to 100 μm; the laminate has an indentation hardness of 850 N/mm² or more when the hard coat layer is an outermost surface; no crack is generated when a pen is dropped to the laminate from a height of 30 mm; and the laminate has a minimum bending diameter at which no crack is generated of 10 mm Φ or less when the laminate is bent with the hard coat layer facing inward.

### TECHNICAL FIELD

The present disclosure relates to a laminate and an image display device. The present application claims priority to JP 2023-010550 filed in Japan on Jan. 26, 2023, the content of which is incorporated herein by reference.

### BACKGROUND ART

As glass used for the display of a television, a personal computer, a smartphone, or the like, a configuration in which a hard coat layer is laminated on its surface for the purpose of not only achieving transparency and aesthetics considered to be important, but also preventing generation of scratches and indentations is known.

Furthermore, in the case of ultra-thin glass (abbreviated as UTG) used for flexible applications, the glass is easily broken by impact. Therefore, an invention in which impact resistance is imparted to a hard coat layer has been known (e.g., Patent Document 1).

### CITATION LIST

### Non-Patent Literature

Patent Document 1: JP 2022-44010 A

### SUMMARY OF INVENTION

### Technical Problem

However, the known inventions including the invention of Patent Document 1 involve a problem that bending resistance becomes poor when the surface hardness of the hard coat layer is increased for the purpose of exhibiting impact resistance.

In addition, when a soft impact absorbing layer is provided for the purpose of providing impact resistance, there are a problem that the surface hardness is not sufficient and that scratches and indentations are likely to be generated, and a problem that touch properties are impaired. Thus, it has been difficult to achieve all three of surface hardness, bending resistance, and impact resistance at high levels.

The present disclosure is intended to solve the above problems, and an object thereof is to provide a laminate having excellent surface hardness, impact resistance, and bending resistance.

### Solution to Problem

The inventors of the present disclosure have found that a laminate having excellent surface hardness, impact resistance, and bending resistance is provided in the case where the laminate includes a glass substrate and a hard coat layer laminated on at least one surface of the glass substrate, in which the thickness of the glass substrate, an indentation hardness, and a minimum bending diameter at which no crack is generated when the laminate is bent with the hard coat layer facing inward are adjusted to certain ranges, and no crack is generated when a pen is dropped to the laminate from a height of 30 mm. The present disclosure has been completed based on these findings.

That is, the present disclosure provides a laminate including a glass substrate and a hard coat layer laminated on at least one surface of the glass substrate, wherein the glass substrate has a thickness of from 1 to 100 μm; the laminate has an indentation hardness of 850 N/mm² or more when the hard coat layer is an outermost surface; no crack is generated when a pen is dropped to the laminate from a height of 30 mm; and the laminate has a minimum bending diameter at which no crack is generated of 10 mm Φ or less when the laminate is bent with the hard coat layer facing inward.

With the above configuration, the present disclosure can provide excellent surface hardness, impact resistance, and bending resistance.

The laminate preferably has a haze value of 1% or less. With the above configuration, the laminate has excellent transparency and can be suitably used in a display device.

The laminate preferably has a total light transmittance of 85% or more. With the above configuration, the laminate has excellent transparency and can be suitably used in a display device.

The hard coat layer preferably has a thickness of 25 μm or more. With the above configuration, the laminate exhibits impact resistance, and it becomes easy to suppress generation of a crack.

Preferably, the hard coat layer is a cured product of a curable composition containing one or more curable compounds, and at least one of the curable compounds is a polyorganosilsesquioxane.

The glass substrate preferably has a minimum bending diameter at which no crack is generated of 10 mm Φ or less when the glass substrate is bent. With the above configurations, the laminate easily exhibits bending resistance.

The present disclosure also provides a display device including the laminate described above.

### Advantageous Effects of Invention

The laminate of the present disclosure has excellent surface hardness, impact resistance, and bending resistance. Therefore, the laminate can be suitably used in an image display device such as a display device.

### DESCRIPTION OF EMBODIMENTS

In the present specification, a “(meth)acryloyl group” means an acryloyl group and/or a methacryloyl group. The “(meth)acrylate” means acrylate and/or methacrylate.

### Laminate

The laminate according to an embodiment of the present disclosure includes a glass substrate and a hard coat layer laminated on at least one surface of the glass substrate, wherein the glass substrate has a thickness of from 1 to 100 μm; the laminate has an indentation hardness of 850 N/mm² or more when the hard coat layer is an outermost surface; no crack is generated when a pen is dropped to the laminate from a height of 30 mm; and the laminate has a minimum bending diameter at which no crack is generated of 10 mm Φ or less when the laminate is bent with the hard coat layer facing inward.

The above laminate may include an additional layer besides the glass substrate and the hard coat layer. Examples of the additional layer can include an undercoat layer for bonding the glass substrate and the hard coat layer and an antireflection layer. The additional layer may be formed on only one surface (one side) of the glass substrate, or the additional layers may be formed on both surfaces (both sides) of the glass substrate. When the additional layers are formed on both surfaces of the glass substrate, the same layers may be laminated on the surfaces, or layers having different thicknesses or compositions may be laminated on the surfaces.

The laminate has a minimum bending diameter at which no crack is generated in a range of 10 mm Φ or less, preferably 8 mm Φ or less, and more preferably 6 μm Φ or less, when the laminate is bent with the hard coat layer facing inward, as measured by the cylindrical mandrel method in accordance with JIS K5600 May 1. When the minimum bending diameter is 10 mm Φ or less, the laminate can exhibit bending resistance. When the hard coat layers having different thicknesses are formed on both surfaces of the laminate, the measurement is performed with the thicker one of the hard coat layers facing inward.

The laminate has an average value of measurement results (indentation hardness) of an indentation load of 850 N/mm² or more, preferably 1000 N/mm² or more, and more preferably 1200 N/mm² or more, when the indentation load is adjusted to 50 UN toward the hard coat layer with the hard coat layer-formed surface as the outermost surface. The upper limit is not particularly limited, but is preferably 5000 N/mm² or less, more preferably 3000 N/mm² or less, and even more preferably 2000 N/mm² or less from the viewpoint of exhibiting bending resistance. When the indentation hardness is 850 N/mm² or more, the laminate has sufficient surface hardness, and has excellent touch properties when used as a touch panel. When the hard coat layers are formed on both surfaces of the laminate, the indentation hardness is measured with the thicker one of the hard coat layers as the outermost surface. The laminate does not crack in an impact resistance test (pen drop test) described in Examples below. In the pen drop test, the laminate preferably does not crack even in a state where the hard coat layer is formed only on one surface of the laminate and the hard coat layer or the additional layer is not formed on the other surface. When the hard coat layers are formed on both surfaces of the laminate, the impact resistance is measured with the thicker one of the hard coat layers as the outermost surface.

The laminate has a haze value of preferably 1.0% or less, more preferably 0.8% or less, even more preferably 0.6% or less, and particularly preferably 0.5% or less. When the haze value is 1.0% or less, transparency is easily secured.

The laminate has a total light transmittance of preferably 85% or more, more preferably 88% or more, and particularly preferably 91% or more. When the total light transmittance is 85% or more, transparency is easily secured.

The thickness of the laminate is preferably from 26 to 250 μm, more preferably from 30 to 200 μm, and particularly preferably from 35 to 150 μm. When the thickness of the laminate is 26 μm or more, the laminate exhibits impact resistance, and it becomes easy to suppress generation of a crack. Meanwhile, when the thickness is 250 μm or less, the laminate easily exhibits bending resistance.

### Glass Substrate

From the viewpoint of exhibiting bending resistance, the glass substrate has a minimum bending diameter at which no crack is generated of preferably 10 mm Φ or less, more preferably 8 mm Φ or less, and particularly preferably 6 mm Φ or less, as measured by the cylindrical mandrel method in accordance with JIS K5600 May 1. When the minimum bending diameter at which no crack is generated of the glass substrate is 10 mm Φ or less, the laminate easily exhibits bending resistance. From the viewpoint of exhibiting bending resistance, the minimum bending diameter at which no crack is generated of the glass substrate alone is preferably smaller than the minimum bending diameter at which no crack is generated of the laminate.

The glass substrate may be chemically strengthened from the viewpoints of improving strength against cracking when the glass is made thin and configuring a panel that is durable enough for practical use. Moreover, the glass substrate is preferably subjected to end face treatment from the viewpoint of making a substrate with sufficient strength. The glass substrate may have not only a single-layer configuration but also a double-layer configuration. Furthermore, for the purpose of improving abrasion resistance, smoothness, and strength against cracking, a treated layer or a coating film may be formed on either surface.

The thickness of the glass substrate is preferably from 1 to 100 μm, more preferably from 5 to 80 μm, and particularly preferably from 10 to 60 μm. When the thickness of the glass substrate is 1 μm or more, the glass substrate easily exhibits sufficient strength as a substrate. When the thickness of the glass substrate is 100 μm or less, the glass substrate easily exhibits bending resistance.

### Hard Coat Layer

The laminate can be produced by further forming the hard coat layer on the glass substrate. In the laminate, the hard coat layer preferably has sufficient surface hardness while suppressing the generation of a crack in the laminate, even when the hard coat layer is formed on only one surface (one side) of the glass substrate. The hard coat layers may be formed on both surfaces (both sides) of the glass substrate. When the hard coat layers are formed on both surfaces of the glass substrate, the same hard coat layers may be laminated on the surfaces, or hard coat layers having different thicknesses or compositions may be laminated on the surfaces. In addition, the hard coat layer may be formed on one surface of the glass substrate, and the additional layer described above may be formed on the other surface. From the viewpoint of suppressing the generation of a crack, preferably, the hard coat layer is formed on at least one surface of the glass substrate, and the hard coat layer or the additional layer is formed on the other surface.

The hard coat layer is preferably a hard coat layer containing a curable resin. Examples of the curable resin include a curable polyorganosilsesquioxane resin and a curable acrylic resin, and the curable polyorganosilsesquioxane resin is preferable from the viewpoint of improving surface hardness. The curable resin is preferably a cured product of a curable composition containing a curable compound. That is, the curable compound for forming the hard coat layer preferably contains a polyorganosilsesquioxane.

The polyorganosilsesquioxane preferably contains a polyorganosilsesquioxane having a constituent unit represented by Formula (1) below (hereinafter may be referred to as “the polyorganosilsesquioxane of the present disclosure”). That is, the curable composition for forming the hard coat layer (hereinafter may be referred to as “hard coating agent”) preferably contains a polyorganosilsesquioxane having a constituent unit represented by Formula (1) below. As described below, the hard coating agent may contain an additional component, such as a curing agent or an antioxidant.

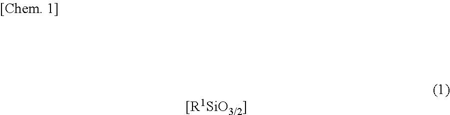

[In Formula (1), R¹ represents a group containing an active energy ray-curable functional group.]

The polyorganosilsesquioxane of the present disclosure is characterized by having a constituent unit represented by Formula (1) above. The polyorganosilsesquioxane of the present disclosure preferably has a constituent unit represented by Formula (I) below (which may be referred to as “the T3 form”) and a constituent unit represented by Formula (II) below (which may be referred to as “the T2 form”). Furthermore, the polyorganosilsesquioxane of the present disclosure preferably has a constituent unit represented by Formula (2) described below.

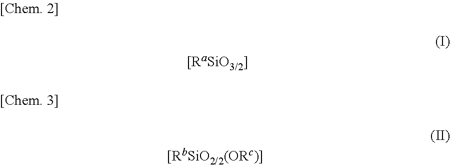

The constituent unit represented by Formula (1) above is a silsesquioxane constituent unit (so-called T unit) generally represented by [RSiO_{3/2}]. R in the formula above represents a hydrogen atom or a monovalent organic group, and the same shall apply hereinafter. The constituent unit represented by Formula (1) above is formed by hydrolysis and condensation reaction of a corresponding hydrolyzable trifunctional silane compound (specifically, e.g., a compound represented by Formula (a) described below).

R¹ in Formula (1) represents a group (monovalent group) containing an active energy ray-curable functional group. That is, the polyorganosilsesquioxane of the present disclosure is a photocationically curable compound (photocationically polymerizable compound) or a photoradically curable compound (photoradically polymerizable compound), the curable compound having at least an active energy ray-curable functional group in the molecule.

The “photocationically polymerizable functional group” in the group containing an active energy ray-curable functional group is not particularly limited as long as it is photocationically polymerizable, and examples of the group include an epoxy group, an oxetane group, a vinyl ether group, and a vinylphenyl group. The “photoradically polymerizable functional group” in the group containing an active energy ray-curable functional group is not particularly limited as long as it is photoradically polymerizable, and examples of the group include a (meth)acryloxy group, a (meth)acrylamide group, a vinyl group, and a vinylthio group. From the viewpoint of surface hardness (e.g., H or more) of the cured product (coating film), the active energy ray-curable functional group is preferably an epoxy group, a (meth)acryloxy group, or the like, and is particularly preferably an epoxy group.

Examples of the group containing an epoxy group include a known or commonly used group having an oxirane ring and are not particularly limited. However, from the viewpoint of the curability of the hard coating agent, and the scratch resistance and toughness of the cured product (coating film), the group is preferably a group represented by Formula (1a) below, a group represented by Formula (1b) below, a group represented by Formula (1c) below, or a group represented by Formula (1d) below, more preferably a group represented by Formula (1a) below or a group represented by Formula (1c) below, and even more preferably a group represented by Formula (1a) below.

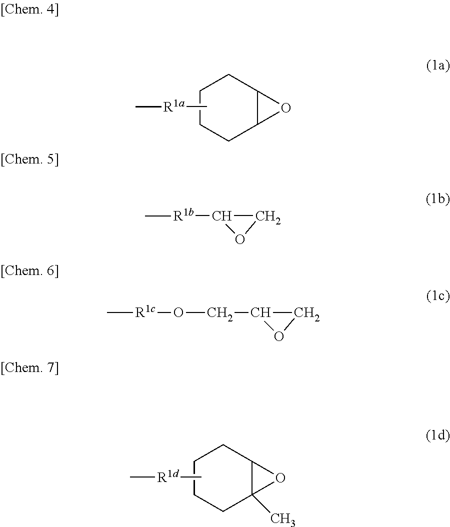

In Formula (1a) above, R^{1a} represents a linear or branched alkylene group. Examples of the linear or branched alkylene group include linear or branched alkylene groups having from 1 to 10 carbons, such as a methylene group, a methylmethylene group, a dimethylmethylene group, an ethylene group, a propylene group, a trimethylene group, a tetramethylene group, a pentamethylene group, a hexamethylene group, and a decamethylene group. Among these, from the viewpoint of the scratch resistance and toughness of the cured product (coating film), R^{1a} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1b) above, R^{1b} represents a linear or branched alkylene group, and examples thereof include groups similar to those exemplified as R^{1a}. Among these, from the viewpoint of the scratch resistance and toughness of the cured product (coating film), R^{1b} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1c) above, R^{1c} represents a linear or branched alkylene group, and examples thereof include groups similar to those exemplified as R^{1a}. Among these, from the viewpoint of the scratch resistance and toughness of the cured product (coating film), R^{1c} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1d) above, R^{1d} represents a linear or branched alkylene group, and examples thereof include groups similar to those exemplified as R^{1a}. Among these, from the viewpoint of the scratch resistance and toughness of the cured product (coating film), R^{1d} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

From the viewpoint of the scratch resistance and toughness of the cured product (coating film), R¹ in Formula (1) is particularly preferably a group represented by Formula (1a) above wherein R^{1a} is an ethylene group [among others, a 2-(3′,4′-epoxycyclohexyl)ethyl group].

Examples of the group containing an oxetane group include a known or commonly used group having an oxetane ring and are not particularly limited. However, examples include an oxetane group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with an oxetane group. From the viewpoint of the curability of the hard coating agent, and the scratch resistance and toughness of the cured product (coating film), the group is preferably a 3-oxetanyl group, an oxetan-3-ylmethyl group, a 3-ethyloxetan-3-ylmethyl group, a 2-(oxetan-3-yl)ethyl group, a 2-(3-ethyloxetan-3-yl)ethyl group, a 3-(oxetan-3-ylmethoxy)propyl group, a 3-(3-ethyloxetan-3-ylmethoxy)propyl group, or the like.

Examples of the group containing a vinyl ether group include a known or commonly used group having a vinyl ether group and are not particularly limited. However, examples include a vinyl ether group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a vinyl ether group. From the viewpoint of the curability of the hard coating agent, and the scratch resistance and toughness of the cured product (coating film), the group is preferably a vinyloxymethyl group, a 2-(vinyloxy)ethyl group, a 3-(vinyloxy)propyl group, or the like.

Examples of the group containing a vinylphenyl group include a known or commonly used group having a vinylphenyl group and are not particularly limited. However, examples include a vinylphenyl group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a vinylphenyl group. From the viewpoint of the curability of the hard coating agent, and the scratch resistance and toughness of the cured product (coating film), the group is preferably a 4-vinylphenyl group, a 3-vinylphenyl group, a 2-vinylphenyl group, or the like.

Examples of the group containing a (meth)acryloxy group include a known or commonly used group having a (meth)acryloxy group and are not particularly limited. However, examples include a (meth)acryloxy group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a (meth)acryloxy group. From the viewpoint of the curability of the hard coating agent (coating film), and the scratch resistance and toughness of the cured product (coating film), the group is preferably a 2-((meth)acryloxy)ethyl group, a 3-((meth)acryloxy)propyl group, or the like.

Examples of the group containing a (meth)acrylamide group include a known or commonly used group having a (meth)acrylamide group and are not particularly limited. However, examples include a (meth)acrylamide group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a (meth)acrylamide group. From the viewpoint of the curability of the hard coating agent, and the scratch resistance and toughness of the cured product (coating film), the group is preferably a 2-((meth)acrylamide)ethyl group, a 3-((meth)acrylamide) propyl group, or the like.

Examples of the group containing a vinyl group include a known or commonly used group having a vinyl group and are not particularly limited. However, examples include a vinyl group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a vinyl group. From the viewpoint of the curability of the hard coating agent, and the scratch resistance and toughness of the cured product (coating film), the group is preferably a vinyl group, a vinylmethyl group, a 2-vinylethyl group, a 3-vinylpropyl group, or the like.

Examples of the group containing a vinylthio group include a known or commonly used group having a vinylthio group and are not particularly limited. However, examples include a vinylthio group itself and a group obtained by substituting a hydrogen atom (usually one or more hydrogen atoms, and preferably one hydrogen atom) of an alkyl group (alkyl group having preferably from 1 to 10 carbons and more preferably from 1 to 5 carbons) with a vinylthio group. From the viewpoint of the curability of the hard coating agent, and the scratch resistance and toughness of the cured product (coating film), the group is preferably a vinylthiomethyl group, a 2-(vinylthio)ethyl group, a 3-(vinylthio) propyl group, or the like.

From the viewpoint of the scratch resistance and toughness of the cured product (coating film), R¹ in Formula (1) is preferably a group containing an epoxy group or a group containing a (meth)acryloxy group, and is particularly preferably a group represented by Formula (1a) above wherein R^{1a} is an ethylene group [among others, a 2-(3′,4′-epoxycyclohexyl)ethyl group], a 3-(acryloxy)propyl group, or a 3-(methacryloxy)propyl group.

The polyorganosilsesquioxane of the present disclosure may have only one type of constituent unit represented by Formula (1) above or may have two or more types of constituent units represented by Formula (1) above.

The polyorganosilsesquioxane of the present disclosure may also have, as the silsesquioxane constituent unit [RSiO_{3/2}], a constituent unit represented by Formula (2) below in addition to the constituent unit represented by Formula (1) above.

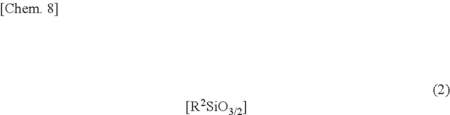

The constituent unit represented by Formula (2) above is a silsesquioxane constituent unit (T unit) generally represented by [RSiO_{3/2}]. That is, the constituent unit represented by Formula (2) above is formed by hydrolysis and condensation reaction of a corresponding hydrolyzable trifunctional silane compound (specifically, for example, a compound represented by Formula (b) described below).

R² in Formula (2) above represents a substituted or unsubstituted aryl group, a substituted or unsubstituted aralkyl group, a substituted or unsubstituted cycloalkyl group, a substituted or unsubstituted alkyl group, or a substituted or unsubstituted alkenyl group. Examples of the aryl group include a phenyl group, a tolyl group, and a naphthyl group. Examples of the aralkyl group include a benzyl group and a phenethyl group. Examples of the cycloalkyl group include a cyclobutyl group, a cyclopentyl group, and a cyclohexyl group. Examples of the alkyl group include linear or branched alkyl groups, such as a methyl group, an ethyl group, a propyl group, an n-butyl group, an isopropyl group, an isobutyl group, an s-butyl group, a t-butyl group, and an isopentyl group. Examples of the alkenyl group include linear or branched alkenyl groups, such as a vinyl group, an allyl group, and an isopropenyl group.

Examples of the substituted aryl group, the substituted aralkyl group, the substituted cycloalkyl group, the substituted alkyl group, and the substituted alkenyl group described above include a group in which one, some, or all of hydrogen atoms or part or the whole of the main chain backbone in each of the aryl group, the aralkyl group, the cycloalkyl group, the alkyl group, and the alkenyl group described above are substituted with at least one selected from the group consisting of an ether group, an ester group, a carbonyl group, a siloxane group, a halogen atom (such as a fluorine atom), an acrylic group, a methacrylic group, a mercapto group, an amino group, and a hydroxy group (hydroxyl group).

Among these, R² is preferably a substituted or unsubstituted aryl group, a substituted or unsubstituted alkyl group, or a substituted or unsubstituted alkenyl group, more preferably a substituted or unsubstituted aryl group, and even more preferably a phenyl group.

The proportion of each of the silsesquioxane constituent units described above (the constituent unit represented by Formula (1) and the constituent unit represented by Formula (2)) in the polyorganosilsesquioxane of the present disclosure can be appropriately adjusted by the composition of the raw materials (hydrolyzable trifunctional silanes) for forming these constituent units.

The polyorganosilsesquioxane of the present disclosure may further have at least one type of siloxane constituent unit selected from the group consisting of a silsesquioxane constituent unit [RSiO_{3/2}] other than the constituent unit represented by Formula (1) above and the constituent unit represented by Formula (2) above; a constituent unit represented by [R³SiO_{1/2}] (so-called “M unit”); a constituent unit represented by [R²SiO_{2/2}] (so-called “D unit”); and a constituent unit represented by [SiO_{4/2}] (so-called “Q unit”). Examples of the silsesquioxane constituent unit other than the constituent unit represented by Formula (1) above and the constituent unit represented by Formula (2) above include a constituent unit represented by Formula (3) below.

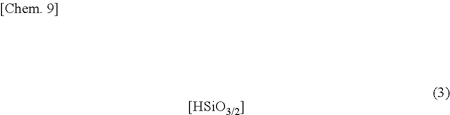

In the case where the polyorganosilsesquioxane of the present disclosure has the constituent unit (T3 form) represented by Formula (I) above and the constituent unit (T2 form) represented by Formula (II) above, the ratio [T3 form/T2 form] is not particularly limited but, for example, can be appropriately selected from a range of 5 or more (e.g., 5 or more and 500 or less). The lower limit value of the ratio [T3 form/T2 form] is preferably 20, more preferably 21, even more preferably 23, and still more preferably 25. Adjusting the ratio [T3 form/T2 form] to 5 or more tends to improve the surface hardness, scratch resistance, and toughness of the cured product (coating film). Meanwhile, the upper limit value of the ratio [T3 form/T2 form] is preferably 500, more preferably 100, even more preferably 50, and still more preferably 40. Adjusting the ratio [T3 form/T2 form] to 500 or less improves the compatibility with other components in the hard coating agent and also reduces viscosity, thus facilitating handling and application as a hard coating agent.

The constituent unit represented by Formula (I) above is represented by Formula (I′) below in more detail. Furthermore, the constituent unit represented by Formula (II) above is represented by Formula (II′) below in more detail. Three oxygen atoms bonded to the silicon atom illustrated in the structure represented by formula (I′) below are each bonded to another silicon atom (a silicon atom not illustrated in formula (I′)). Meanwhile, two oxygen atoms located above and below the silicon atom illustrated in the structure represented by Formula (II′) below are each bonded to another silicon atom (a silicon atom not illustrated in Formula (II′)). That is, the T3 form and the T2 form are each a constituent unit (T unit) formed by the hydrolysis and condensation reaction of the corresponding hydrolyzable trifunctional silane compound.

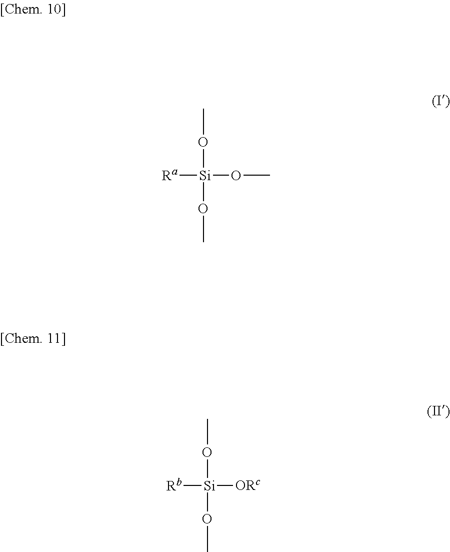

R^{a} in Formula (I) above (likewise, R^{a} in Formula (I′)) and R^{b} in Formula (II) above (likewise, R^{b} in Formula (II′)) each represent a group containing an active energy ray-curable functional group, a substituted or unsubstituted aryl group, a substituted or unsubstituted aralkyl group, a substituted or unsubstituted cycloalkyl group, a substituted or unsubstituted alkyl group, a substituted or unsubstituted alkenyl group, or a hydrogen atom. Specific examples of R^{a} and R^{b} include those similar to those exemplified as R¹ in Formula (I) above and R² in Formula (2) above. R^{a} in Formula (I) and R^{b} in Formula (II) are each derived from a group (a group other than an alkoxy group and a halogen atom; e.g., R¹, R², a hydrogen atom, and the like in Formulae (a) to (c) described below) bonded to a silicon atom in the hydrolyzable trifunctional silane compound used as a raw material for the polyorganosilsesquioxane of the present disclosure.

R^{c} in Formula (II) above (and also Re in Formula (II′)) represents a hydrogen atom or an alkyl group having from 1 to 4 carbons. Examples of the alkyl group having from 1 to 4 carbons include linear or branched alkyl groups having from 1 to 4 carbons, such as a methyl group, an ethyl group, a propyl group, an isopropyl group, a butyl group, and an isobutyl group. The alkyl group of Re in Formula (II) is generally derived from an alkyl group that forms an alkoxy group (e.g., an alkoxy group as X¹ to X³ described below) in the hydrolyzable silane compound used as a raw material for the polyorganosilsesquioxane of the present disclosure.

The ratio [T3 form/T2 form] in the polyorganosilsesquioxane of the present disclosure can be determined, for example, by ²⁹Si-NMR spectroscopic measurement. In the ²⁹Si-NMR spectrum, the silicon atom in the constituent unit represented by Formula (I) above (T3 unit) and the silicon atom in the constituent unit represented by Formula (II) above (T2 unit) exhibit signals (peaks) at different positions (chemical shifts). Thus, the ratio [T3 unit/T2 unit] can be determined by calculating the integration ratio of these peaks. Specifically, for example, in the case where the polyorganosilsesquioxane of the present disclosure has a constituent unit represented by Formula (I) above wherein R¹ is a 2-(3′,4′-epoxycyclohexyl)ethyl group, the signal of the silicon atom in the structure represented by Formula (I) above (T3 form) appears at −64 to −70 ppm, and the signal of the silicon atom in the structure represented by Formula (II) above (T2 form) appears at −54 to −60 ppm. Thus, in this case, the above [T3 form/T2 form] ratio can be determined by calculating the integration ratio of the signal at −64 to −70 ppm (T3 form) and the signal at −54 to −60 ppm (T2 form). Also in the case where R¹ is a group containing an active energy ray-curable functional group other than the 2-(3′,4′-epoxycyclohexyl)ethyl group, the [T3 form/T2 form] can be determined in the same manner.

The ²⁹Si-NMR spectrum of the polyorganosilsesquioxane of the present disclosure can be measured, for example, with the following instrument and conditions.
Measuring instrument: trade name “JNM-ECA500 NMR” (available from JEOL Ltd.)
Solvent: deuterochloroform
Cumulative number of times: 1800
Measurement temperature: 25° C.

The case where the ratio [T3 form/T2 form] of the polyorganosilsesquioxane of the present disclosure is in the above range (e.g., 5 or more and 500 or less) means that a certain amount of the T2 form is present relative to the amount of the T3 form in the polyorganosilsesquioxane of the present disclosure. Examples of the T2 form include a constituent unit represented by Formula (4) below, a constituent unit represented by Formula (5) below, and a constituent unit represented by Formula (6) below. R¹ in Formula (4) below and R² in Formula (5) below are the same as R¹ in Formula (1) above and R² in Formula (2) above, respectively. R^{c} in Formulae (4) to (6) below represents a hydrogen atom or an alkyl group having from 1 to 4 carbons, as with Re in Formula (II).

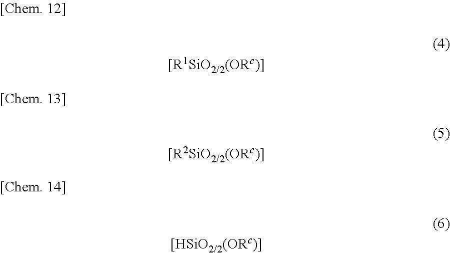

The polyorganosilsesquioxane of the present disclosure may have any silsesquioxane structure of a cage-type, an incomplete cage-type, a ladder-type, or a random-type or may have a combination of two or more of these silsesquioxane structures.

In the case where the polyorganosilsesquioxane of the present disclosure has a constituent unit represented by Formula (4) above, the ratio (total amount) of the constituent unit represented by Formula (1) above and the constituent unit represented by Formula (4) above to the total amount (100 mol %) of siloxane constituent units [all siloxane constituent units; the total amount of the M unit, the D unit, the T unit, and the Q unit] is not particularly limited, but is preferably from 55 to 100 mol %, more preferably from 65 to 100 mol %, and even more preferably from 80 to 99 mol %. Adjusting the ratio to 55 mol % or more improves the curability of the hard coating agent and also significantly increases the scratch resistance and toughness of the cured product (coating film). The proportion of each siloxane constituent unit in the polyorganosilsesquioxane of the present disclosure can be calculated, for example, from the composition of the raw materials or by NMR spectroscopic measurement.

The ratio (total amount) of the constituent unit represented by Formula (2) above and the constituent unit represented by Formula (5) above to the total amount (100 mol %) of siloxane constituent units [all siloxane constituent units; the total amount of the M unit, the D unit, the T unit, and the Q unit] in the polyorganosilsesquioxane of the present disclosure is not particularly limited, but is preferably from 0 to 70 mol %, more preferably from 0 to 60 mol %, even more preferably from 0 to 40 mol %, and particularly preferably from 1 to 15 mol %. Adjusting the ratio to 70 mol % or less can relatively increase the proportions of the constituent unit represented by Formula (1) and the constituent unit represented by Formula (4), thus resulting in a tendency to improve the curability of the hard coating agent and further increase the scratch resistance and toughness of the cured product (coating film).

The ratio (total amount) of the constituent unit represented by Formula (1) above, the constituent unit represented by Formula (2) above, the constituent unit represented by Formula (4) above, and the constituent unit represented by Formula (5) above to the total amount (100 mol %) of siloxane constituent units [all siloxane constituent units; the total amount of the M unit, the D unit, the T unit, and the Q unit] in the polyorganosilsesquioxane of the present disclosure is not particularly limited, but is preferably from 60 to 100 mol %, more preferably from 70 to 100 mol %, and even more preferably from 80 to 100 mol %. Adjusting the ratio to 60 mol % or more tends to further increase the scratch resistance and toughness of the cured product (coating film).

The number average molecular weight (Mn) of the polyorganosilsesquioxane of the present disclosure determined by gel permeation chromatography and calibrated with standard polystyrene is not particularly limited, but, for example, can be appropriately selected from a range of 1000 to 50000. The lower limit value of the number average molecular weight is preferably 1500, more preferably 1800, and even more preferably 2000. Adjusting the number average molecular weight to 1000 or more tends to further improve the scratch resistance and toughness of the cured product (coating film). Meanwhile, the upper limit value of the number average molecular weight is preferably 50000, more preferably 10000, and even more preferably 8000. Adjusting the number average molecular weight to 50000 or less (e.g., 3000 or less) tends to improve the compatibility with other components in the hard coating agent and improve the scratch resistance and toughness of the cured product (coating film).

The molecular weight dispersity (Mw/Mn) of the polyorganosilsesquioxane of the present disclosure determined by gel permeation chromatography and calibrated with standard polystyrene is not particularly limited, but can be appropriately selected from a range of 1.0 to 4.0. The lower limit value of the molecular weight dispersity is preferably 1.0, more preferably 1.1, and even more preferably 1.2. Adjusting the molecular weight dispersity to 1.1 or more tends to make it easier for the hard coating agent to become a liquid and to improve handling properties. Meanwhile, the upper limit value of the molecular weight dispersity is preferably 4.0, more preferably 3.0, and even more preferably 2.5. Adjusting the molecular weight dispersity to 4.0 or less tends to further increase the scratch resistance and toughness of the cured product (coating film).

The number average molecular weight and the molecular weight dispersity of the polyorganosilsesquioxane of the present disclosure can be measured with the following instruments and conditions.
Measuring instrument: trade name “LC-20AD” (available from Shimadzu Corporation)
Columns: Shodex KF-801×2, KF-802, and KF-803 (available from Showa Denko K.K.)
Measurement temperature: 40° C.
Eluent: THF, sample concentration of from 0.1 to 0.2 mass %
Flow rate: 1 mL/min
Detector: UV-VIS detector (trade name “SPD-20A”, available from Shimadzu Corporation)
Molecular weight: calibrated with standard polystyrene

The 5% weight loss temperature (T_{d5}) of the polyorganosilsesquioxane of the present disclosure in an air atmosphere is not particularly limited, but is preferably 330° C. or higher (e.g., from 330 to 450° C.), more preferably 340° C. or higher, and even more preferably 350° C. or higher. When the 5% weight loss temperature is 330° C. or higher, the scratch resistance and toughness of the cured product (coating film) tend to further improve. In particular, in the polyorganosilsesquioxane of the present disclosure, when the ratio [T3 form/T2 form] is 5 or more and 500 or less, the number average molecular weight is 1000 to 50000, and the molecular weight dispersity is 1.0 to 4.0, the 5% weight loss temperature is controlled to 330° C. or higher. The 5% weight loss temperature is a temperature at which the weight decreases by 5% of the weight before heating when heating is performed at a constant temperature increase rate, and is an index of heat resistance. The 5% weight loss temperature can be measured by thermogravimetric analysis (TGA) under conditions of a temperature increase rate of 5° C./min in an air atmosphere.

The polyorganosilsesquioxane of the present disclosure can be produced by a known or commonly used method for producing a polysiloxane. The method is not particularly limited, but for example, the polyorganosilsesquioxane can be produced by a method of subjecting one hydrolyzable silane compound or two or more hydrolyzable silane compounds to hydrolysis and condensation. As the aforementioned hydrolyzable silane compound, however, a hydrolyzable trifunctional silane compound (compound represented by Formula (a) below) for forming the constituent unit represented by Formula (1) described above needs to be used as an essential hydrolyzable silane compound.

More specifically, for example, the polyorganosilsesquioxane of the present disclosure can be produced by a method of hydrolysis and condensation of a compound represented by Formula (a) below, which is a hydrolyzable silane compound for forming the silsesquioxane constituent unit (T unit) in the polyorganosilsesquioxane of the present disclosure, and, additionally as necessary, a compound represented by Formula (b) below and a compound represented by Formula (c) below.

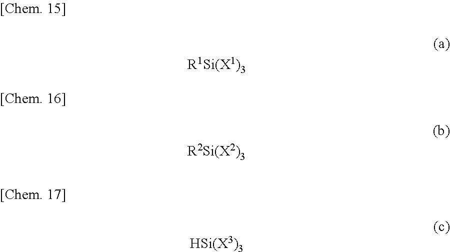

The compound represented by Formula (a) above is a compound that forms the constituent unit represented by Formula (1) in the polyorganosilsesquioxane of the present disclosure. R¹ in Formula (a) represents a group containing an active energy ray-curable functional group, as in the case of R¹ in Formula (1) above. That is, R¹ in Formula (a) is preferably a group represented by Formula (1a) above, a group represented by Formula (1b) above, a group represented by Formula (1c) above, or a group represented by Formula (1d) above, more preferably a group represented by Formula (1a) above or a group represented by Formula (1c) above, even more preferably a group represented by Formula (1a) above, and particularly preferably a group represented by Formula (1a) above wherein R^{1a} is an ethylene group [in particular, a 2-(3′,4′-epoxycyclohexyl)ethyl group]. As described above, the R¹ in Formula (a) is also preferably a 3-(acryloxy)propyl group or a 3-(methacryloxy)propyl group.

X¹ in Formula (a) above represents an alkoxy group or a halogen atom. Examples of the alkoxy group of X¹ include alkoxy groups having from 1 to 4 carbons, such as a methoxy group, an ethoxy group, a propoxy group, an isopropyloxy group, a butoxy group, and an isobutyloxy group. Examples of the halogen atom of X¹ include a fluorine atom, a chlorine atom, a bromine atom, and an iodine atom. Among these, X¹ is preferably an alkoxy group, and more preferably a methoxy group or an ethoxy group. The three X¹s may be the same or different.

The compound represented by Formula (b) above is a compound that forms the constituent unit represented by Formula (2) in the polyorganosilsesquioxane of the present disclosure. R² in Formula (b) represents, as in the case of R² in Formula (2) above, a substituted or unsubstituted aryl group, a substituted or unsubstituted aralkyl group, a substituted or unsubstituted cycloalkyl group, a substituted or unsubstituted alkyl group, or a substituted or unsubstituted alkenyl group. That is, R² in Formula (b) is preferably a substituted or unsubstituted aryl group, a substituted or unsubstituted alkyl group, or a substituted or unsubstituted alkenyl group, more preferably a substituted or unsubstituted aryl group, and even more preferably a phenyl group.

X² in Formula (b) above represents an alkoxy group or a halogen atom. Specific examples of X² include those exemplified as X¹. Among these, X² is preferably an alkoxy group, and more preferably a methoxy group or an ethoxy group. The three X²s may be the same or different.

The compound represented by Formula (c) above is a compound that forms the constituent unit represented by Formula (3) in the polyorganosilsesquioxane of the present disclosure. X³ in Formula (c) above represents an alkoxy group or a halogen atom. Specific examples of X³ include those exemplified as X¹. Among these, X³ is preferably an alkoxy group, and more preferably a methoxy group or an ethoxy group. The three X³s may be the same or different.

A hydrolyzable silane compound other than the compounds represented by Formulae (a) to (c) above may be used in combination as the aforementioned hydrolyzable silane compound. Examples of the compound include a hydrolyzable trifunctional silane compound other than the compounds represented by Formulae (a) to (c) above, a hydrolyzable monofunctional silane compound forming an M unit, a hydrolyzable bifunctional silane compound forming a D unit, and a hydrolyzable tetrafunctional silane compound forming a Q unit.

The amount of the hydrolyzable silane compound to be used and the composition thereof can be appropriately adjusted according to a desired structure of the polyorganosilsesquioxane of the present disclosure. For example, the amount of the compound represented by Formula (a) above to be used is not particularly limited, but is preferably from 55 to 100 mol %, more preferably from 65 to 100 mol %, and even more preferably from 80 to 99 mol %, relative to the total amount (100 mol %) of the hydrolyzable silane compounds used.

The amount of the compound represented by Formula (b) above to be used is not particularly limited, but is preferably from 0 to 70 mol %, more preferably from 0 to 60 mol %, even more preferably from 0 to 40 mol %, and particularly preferably from 1 to 15 mol %, relative to the total amount (100 mol %) of the hydrolyzable silane compounds used.

Furthermore, the proportion (proportion of the total amount) of the compound represented by Formula (a) and the compound represented by Formula (b) relative to the total amount (100 mol %) of the hydrolyzable silane compounds used is preferably from 60 to 100 mol %, more preferably from 70 to 100 mol %, and even more preferably from 80 to 100 mol %.

In a case where two or more types of the hydrolyzable silane compounds are used in combination, the hydrolyses and the condensation reactions of these hydrolyzable silane compounds can be performed simultaneously or sequentially. When the above reactions are performed sequentially, the order of performing the reactions is not particularly limited.

The hydrolysis and condensation reaction of the hydrolyzable silane compound may be performed in one step or may be performed in two or more steps. For example, for efficiently producing the polyorganosilsesquioxane of the present disclosure with the ratio [T3 form/T2 form] of less than 20 and/or a number average molecular weight of less than 2500 (hereinafter may be referred to as “low molecular weight polyorganosilsesquioxane”), the hydrolysis and condensation reaction are preferably performed in one step. For efficiently producing the polyorganosilsesquioxane of the present disclosure with the ratio [T3 form/T2 form] of 20 or more and/or a number average molecular weight of 2500 or more (hereinafter may be referred to as “high molecular weight polyorganosilsesquioxane”), the hydrolysis and condensation reaction are preferably performed in two or more steps (preferably two steps), that is, the hydrolysis and condensation reaction are preferably performed one or more times using the low molecular weight polyorganosilsesquioxane as a raw material. Next will be described an embodiment in which a low molecular weight polyorganosilsesquioxane is formed by performing hydrolysis and condensation reaction of the hydrolyzable silane compound in one step, and then the low molecular weight polyorganosilsesquioxane is further subjected to hydrolysis and condensation reaction, thereby forming a high molecular weight polyorganosilsesquioxane. However, the method for producing the polyorganosilsesquioxane of the present disclosure is not limited thereto.

When the hydrolysis and condensation reaction according to an embodiment of the present disclosure are performed in two steps, preferably, in the hydrolysis and condensation reaction in the first step, a low molecular weight polyorganosilsesquioxane having the ratio [T3 form/T2 form] of 5 or more and less than 20 and a number average molecular weight of 1000 or more and less than 2500 is formed, and, in the hydrolysis and condensation reaction in the second step, the low molecular weight polyorganosilsesquioxane is further subjected to the hydrolysis and condensation reaction, whereby a high molecular weight polyorganosilsesquioxane having the ratio [T3 form/T2 form] of 20 or more and 500 or less and a number average molecular weight of 2500 or more and 50000 or less can be formed.

The hydrolysis and condensation reaction in the first step can be performed in the presence or absence of a solvent. In particular, the hydrolysis and condensation reaction are preferably performed in the presence of a solvent. Examples of the solvent include aromatic hydrocarbons, such as benzene, toluene, xylene, and ethylbenzene; ethers, such as diethyl ether, dimethoxyethane, tetrahydrofuran, and dioxane; ketones, such as acetone, methyl ethyl ketone, and methyl isobutyl ketone; esters, such as methyl acetate, ethyl acetate, isopropyl acetate, and butyl acetate; amides, such as N,N-dimethylformamide and N,N-dimethylacetamide; nitriles, such as acetonitrile, propionitrile, and benzonitrile; and alcohols, such as methanol, ethanol, isopropyl alcohol, and butanol. Among these, the solvent is preferably a ketone or an ether. One type of the solvent may be used alone, or two or more types thereof may be used in combination.

The amount of the solvent used in the hydrolysis and condensation reaction in the first step is not particularly limited, and can be appropriately adjusted in a range of from 0 to 2000 parts by mass relative to 100 parts by mass of the total amount of the hydrolyzable silane compounds, depending on a desired reaction time or the like.

The hydrolysis and condensation reaction in the first step are preferably allowed to proceed in the presence of a catalyst and water. The catalyst may be an acid catalyst or an alkali catalyst, but an alkali catalyst is preferable in order to suppress decomposition of the active energy ray-curable functional group, such as an epoxy group. Examples of the acid catalyst include mineral acids, such as hydrochloric acid, sulfuric acid, nitric acid, phosphoric acid, and boric acid; phosphate esters; carboxylic acids, such as acetic acid, formic acid, and trifluoroacetic acid; sulfonic acids, such as methanesulfonic acid, trifluoromethanesulfonic acid, and p-toluenesulfonic acid; solid acids, such as activated clay; and Lewis acids, such as iron chloride. Examples of the alkali catalyst include alkali metal hydroxides, such as lithium hydroxide, sodium hydroxide, potassium hydroxide, and cesium hydroxide; alkaline earth metal hydroxides, such as magnesium hydroxide, calcium hydroxide, and barium hydroxide; alkali metal carbonates, such as lithium carbonate, sodium carbonate, potassium carbonate, and cesium carbonate; alkaline earth metal carbonates, such as magnesium carbonate; alkali metal hydrogencarbonates, such as lithium hydrogencarbonate, sodium hydrogencarbonate, potassium hydrogencarbonate, and cesium hydrogencarbonate; alkali metal organic acid salts (e.g., acetates), such as lithium acetate, sodium acetate, potassium acetate, and cesium acetate; organic acid salts (e.g., acetates) of alkaline earth metal, such as magnesium acetate; alkali metal alkoxides, such as lithium methoxide, sodium methoxide, sodium ethoxide, sodium isopropoxide, potassium ethoxide, and potassium t-butoxide; alkali metal phenoxides, such as sodium phenoxide; amines (tertiary amines and the like), such as triethylamine, N-methylpiperidine, 1,8-diazabicyclo[5.4.0]undec-7-ene, and 1,5-diazabicyclo[4.3.0]non-5-ene; and nitrogen-containing aromatic heterocyclic compounds, such as pyridine, 2,2′-bipyridyl, and 1,10-phenanthroline. One type of the catalyst may be used alone, or two or more types thereof may be used in combination. The catalyst may be used in a state of being dissolved or dispersed in water, a solvent, or the like.

The amount of the catalyst used in the hydrolysis and condensation reaction in the first step is not particularly limited, and can be appropriately adjusted in a range of from 0.002 to 0.200 mol relative to the total amount of 1 mol of the hydrolyzable silane compounds.

The amount of water used during the hydrolysis and condensation reaction in the first step is not particularly limited, and can be appropriately adjusted in a range of from 0.5 to 20 mol relative to the total amount of 1 mol of the hydrolyzable silane compounds.

The method for adding water in the hydrolysis and condensation reaction in the first step is not particularly limited, and the total amount of water used (total amount used) may be added all at once or may be added sequentially. When water is added sequentially, it may be added continuously or intermittently.

As reaction conditions for the hydrolysis and condensation reaction in the first step, it is particularly important to select reaction conditions that allow the ratio [T3 form/T2 form] in the low molecular weight polyorganosilsesquioxane to be 5 or more and less than 20. The reaction temperature of the hydrolysis and condensation reaction in the first step is not particularly limited, but is preferably from 40 to 100° C. and more preferably from 45 to 80° C. When the reaction temperature is controlled to the above range, the above ratio [T3 form/T2 form] tends to be more efficiently controlled to 5 or more and less than 20. The reaction time of the hydrolysis and the condensation reaction in the first step is not particularly limited, but is preferably from 0.1 to 10 hours and more preferably from 1.5 to 8 hours. The hydrolysis and condensation reaction in the first step can be performed under normal pressure, or can be performed under increased pressure or reduced pressure. The atmosphere during the hydrolysis and condensation reaction in the first step is not particularly limited, and, for example, the reaction may be performed in any of an inert gas atmosphere such as a nitrogen atmosphere or an argon atmosphere, or in the presence of oxygen such as in the air. The hydrolysis and condensation reaction are preferably performed in the inert gas atmosphere.

The low molecular weight polyorganosilsesquioxane can be formed by the hydrolysis and condensation reaction in the first step. After completion of the hydrolysis and condensation reaction in the first step, the catalyst is preferably neutralized for suppressing decomposition of the active energy ray-curable functional group, such as ring-opening of the epoxy group. Also, the low molecular weight polyorganosilsesquioxane may be separated and purified through, for example, a separation means such as water washing, acid washing, alkali washing, filtration, concentration, distillation, extraction, crystallization, recrystallization, or column chromatography, or a separation means of a combination thereof.

The low molecular weight polyorganosilsesquioxane formed through the hydrolysis and condensation reaction in the first step is subjected to the hydrolysis and condensation reaction in the second step, whereby the high molecular weight polyorganosilsesquioxane can be produced. The hydrolysis and condensation reaction in the second step can be performed in the presence or absence of a solvent. When the hydrolysis and condensation reaction in the second step are performed in the presence of a solvent, a solvent exemplified with regard to the hydrolysis and condensation reaction in the first step can be used. As the solvent of the hydrolysis and condensation reaction in the second step, the low molecular weight polyorganosilsesquioxane containing the reaction solvent and extraction solvent of the hydrolysis and condensation reaction in the first step may be used as is or may be partially distilled off and used. One type of the solvent may be used alone, or two or more types thereof may be used in combination.

In a case where a solvent is used for the hydrolysis and condensation reaction in the second step, the amount of the solvent used is not particularly limited, and can be appropriately adjusted in a range of from 0 to 2000 parts by mass relative to 100 parts by mass of the low molecular weight polyorganosilsesquioxane, depending on the desired reaction time or the like.

The hydrolysis and condensation reaction in the second step are preferably allowed to proceed in the presence of a catalyst and water. The above-described catalyst to be used may be a catalyst exemplified with regard to the hydrolysis and condensation reaction in the first step. For suppressing decomposition of the active energy ray-curable functional group such as an epoxy group, the catalyst is preferably an alkali catalyst, more preferably an alkali metal hydroxide such as sodium hydroxide, potassium hydroxide, or cesium hydroxide, or an alkali metal carbonate, such as lithium carbonate, sodium carbonate, potassium carbonate, or cesium carbonate. One type of the catalyst may be used alone, or two or more types thereof may be used in combination. The catalyst may be used in a state of being dissolved or dispersed in water, a solvent, or the like.

The amount of the catalyst used in the hydrolysis and condensation reaction in the second step is not particularly limited, and can be appropriately adjusted in a range of preferably from 0.01 to 10000 ppm, and more preferably from 0.1 to 1000 ppm, relative to the low molecular weight polyorganosilsesquioxane (1000000 ppm).

The amount of water used during the hydrolysis and condensation reaction in the second step is not particularly limited, and can be appropriately adjusted in a range of preferably from 10 to 100000 ppm, and more preferably from 100 to 20000 ppm, relative to the low molecular weight polyorganosilsesquioxane (1000000 ppm). When the amount of water used is more than 100000 ppm, the [T3 form/T2 form] ratio and the number average molecular weight of the high molecular weight polyorganosilsesquioxane may fail to be easily controlled to the predetermined ranges.

The method for adding water in the hydrolysis and condensation reaction in the second step is not particularly limited, and the total amount of water used (total amount used) may be added all at once or may be added sequentially. When water is added sequentially, it may be added continuously or intermittently.

As reaction conditions for the hydrolysis and condensation reaction in the second step, it is particularly important to select reaction conditions that allow the ratio [T3 form/T2 form] in the high molecular weight polyorganosilsesquioxane to be or more and 500 or less, and the number average molecular weight to be from 2500 to 50000. The reaction temperature of the hydrolysis and condensation reaction in the second step varies depending on the catalyst to be used, and is not particularly limited, 20 but is preferably from 5 to 200° C., and more preferably from 30 to 100° C. When the reaction temperature is controlled to the above range, the [T3 form/T2 form] ratio and the number average molecular weight tend to be more efficiently controlled to the desired ranges. The reaction time of the hydrolysis and the condensation reaction in the second step is not particularly limited, but is preferably from 0.5 to 1000 hours and more preferably from 1 to 500 hours. Also, sampling may be performed at an appropriate time while the hydrolysis and condensation reaction are performed within the reaction temperature range described above, and the reaction may be carried out while the ratio [T3 form/T2 form] and the number average molecular weight are monitored, to thereby form the high molecular weight polyorganosilsesquioxane having the desired ratio [T3 form/T2 form] and number average molecular weight.

The hydrolysis and condensation reaction in the second step can be performed under normal pressure, or can be performed under increased pressure or reduced pressure. The atmosphere during the hydrolysis and condensation reaction in the second step is not particularly limited, and, for example, the reaction may be performed in any of an inert gas atmosphere such as a nitrogen atmosphere or an argon atmosphere, or in the presence of oxygen such as in the air. The hydrolysis and condensation reaction are preferably performed in the inert gas atmosphere.

The high molecular weight polyorganosilsesquioxane can be formed by the hydrolysis and condensation reaction in the second step. After completion of the hydrolysis and condensation reaction in the second step, the catalyst is preferably neutralized for suppressing decomposition of the active energy ray-curable functional group, such as ring-opening of the epoxy group. The high molecular weight polyorganosilsesquioxane may be separated and purified through, for example, a separation means such as water washing, acid washing, alkali washing, filtration, concentration, distillation, extraction, crystallization, recrystallization, or column chromatography, or a separation means of a combination thereof.

The polyorganosilsesquioxane of the present disclosure has the configuration described above, and thus a cured product (coating film) having excellent scratch resistance and toughness can be formed by applying and curing the hard coating agent containing the polyorganosilsesquioxane as an essential component.

In the hard coating agent, one type of the polyorganosilsesquioxane of the present disclosure may be used alone, or two or more types thereof may be used in combination.

The content (blended amount) of the polyorganosilsesquioxane of the present disclosure in the hard coating agent is not particularly limited, but is preferably 70 mass % or more and less than 100 mass %, more preferably from 80 to 99.8 mass %, and even more preferably from 90 to 99.5 mass % relative to the total amount (100 mass %) of the hard coating agent excluding a solvent. Adjusting the content of the polyorganosilsesquioxane of the present disclosure to 70 mass % or more tends to further improve the scratch resistance and toughness of the cured product (coating film). Meanwhile, adjusting the content of the polyorganosilsesquioxane of the present disclosure to less than 100 mass % enables incorporation of a curing agent, resulting in a tendency that curing of the hard coating agent can proceed more efficiently.

The proportion of the polyorganosilsesquioxane of the present disclosure to the total amount (100 mass %) of a photocationically curable compound or photoradically curable compound contained in the hard coating agent is not particularly limited, but is preferably from 70 to 100 mass %, more preferably from 75 to 98 mass %, and even more preferably from 80 to 95 mass %. Adjusting the content of the photocationically curable compound or the photoradically curable compound to 70 mass % or more tends to further improve the scratch resistance and toughness of the cured product (coating film).

The hard coating agent preferably further contains a curing agent to promote curing reaction by irradiation with an activated energy ray. From the viewpoint of shortening the curing time until the hard coating agent becomes tack free, the hard coating agent particularly preferably contains, among others, a photocationic polymerization initiator or photoradical polymerization initiator as the curing agent.

For the photocationic polymerization initiator, the same compound as those disclosed for the photocurable composition described above can be used.

The photoradical polymerization initiator is a compound that can initiate or promote the photoradical polymerization reaction of a photoradically curable compound, such as the polyorganosilsesquioxane of the present disclosure.

Examples of the photoradical polymerization initiator can include benzophenone, acetophenone benzyl, benzyldimethyl ketone, benzoin, benzoin methyl ether, benzoin ethyl ether, benzoin isopropyl ether, dimethoxyacetophenone, dimethoxyphenylacetophenone, diethoxyacetophenone, diphenyl disulfite, methyl o-benzoylbenzoate, ethyl 4-dimethylaminobenzoate, 2,4-diethylthioxanthone, 2-methyl-1-[4-(methyl)phenyl]-2-morpholinopropanone-1, 1-hydroxycyclohexyl phenyl ketone, 2-dimethylamino-2-(4-morpholino)benzoyl-1-phenylpropane, and other such 2-amino-2-benzoyl-1-phenyl alkane compounds, tetra(t-butylperoxycarbonyl)benzophenone, benzil, 2-hydroxy-2-methyl-1-phenyl-propan-1-one, 4,4-bisdiethylaminobenzophenone, and other such amino benzene derivatives, 2,2′-bis 2-chlorophenyl)-4,5,4′,5′-tetraphenyl-1,2′-biimidazole, and other such imidazole compounds, 2,6-bis(trichloromethyl)-4-(4-methoxynaphthalen-1-yl)-1,3,5-triazine, and other such halomethylated triazine compounds, and 2-trichloromethyl-5-(2-benzofuran-2-yl-ethenyl)-1,3,4-oxadiazole, and other such halomethyl oxadiazole compounds. A photosensitizer can be added as necessary.

In the hard coating agent, one type of the curing agent may be used alone, or two or more types thereof may be used in combination.

The content (blended amount) of the curing agent in the hard coating agent is not particularly limited, but is preferably from 0.01 to 10.0 parts by mass, more preferably from 0.05 to 5.0 parts by mass, and even more preferably from 0.1 to 3.0 parts by mass relative to the total amount of the polyorganosilsesquioxane of the present disclosure and an additional active energy ray-curable compound described below (100 parts by mass; the total amount of active energy ray-curable compounds). Adjusting the content of the curing agent to 0.01 parts by mass or more allows the curing reaction to efficiently and sufficiently proceed and tends to further improve the scratch resistance and toughness of the cured product (coating film). Meanwhile, adjusting the content of the curing agent to 5.0 parts by mass or less tends to further improve storage properties of the hard coating agent and to suppress coloration of the cured product (coating film).

The hard coating agent may further contain an active energy ray-curable compound (which may be referred to as an “additional active energy ray-curable compound”) besides the polyorganosilsesquioxane of the present disclosure. Examples of the additional active energy ray-curable compound include a photocationically curable compound (which may be referred to as “additional photocationically curable compound”) besides the polyorganosilsesquioxane of the present disclosure and/or a photoradically curable compound (which may be referred to as “additional photoradically curable compound”) besides the polyorganosilsesquioxane of the present disclosure.

For the additional photocationically curable compound, a known or commonly used photocationically curable compound can be used and is not particularly limited. However, examples include an epoxy compound other than the polyorganosilsesquioxane of the present disclosure, an oxetane compound, and a vinyl ether compound. In the hard coating agent, one type of the additional photocationically curable compound may be used alone, or two or more types thereof may be used in combination.

Examples of the epoxy compound and the oxetane compound can include the same compounds as those described for the photocurable composition.

The vinyl ether compound is not particularly limited, and a well-known or commonly used compound including one or more vinyl ether groups in the molecule can be used. Examples thereof include 2-hydroxyethyl vinyl ether (ethylene glycol monovinyl ether), 3-hydroxypropyl vinyl ether, 2-hydroxypropyl vinyl ether, 2-hydroxyisopropyl vinyl ether, 4-hydroxybutyl vinyl ether, 3-hydroxybutyl vinyl ether, 2-hydroxybutyl vinyl ether, 3-hydroxyisobutyl vinyl ether, 2-hydroxyisobutyl vinyl ether, 1-methyl-3-hydroxypropyl vinyl ether, 1-methyl-2-hydroxypropyl vinyl ether, 1-hydroxymethylpropyl vinyl ether, 4-hydroxycyclohexyl vinyl ether, 1,6-hexanediol monovinyl ether, 1,6-hexanediol divinyl ether, 1,8-octanediol divinyl ether, 1,4-cyclohexanedimethanol monovinyl ether, 1,4-cyclohexanedimethanol divinyl ether, 1,3-cyclohexanedimethanol monovinyl ether, 1,3-cyclohexanedimethanol divinyl ether, 1,2-cyclohexanedimethanol monovinyl ether, 1,2-cyclohexanedimethanol divinyl ether, p-xylene glycol monovinyl ether, p-xylene glycol divinyl ether, m-xylene glycol monovinyl ether, m-xylene glycol divinyl ether, o-xylene glycol monovinyl ether, o-xylene glycol divinyl ether, ethylene glycol divinyl ether, diethylene glycol monovinyl ether, diethylene glycol divinyl ether, triethylene glycol monovinyl ether, triethylene glycol divinyl ether, tetraethylene glycol monovinyl ether, tetraethylene glycol divinyl ether, pentaethylene glycol monovinyl ether, pentaethylene glycol divinyl ether, oligoethylene glycol monovinyl ether, oligoethylene glycol divinyl ether, polyethylene glycol monovinyl ether, polyethylene glycol divinyl ether, dipropylene glycol monovinyl ether, dipropylene glycol divinyl ether, tripropylene glycol monovinyl ether, tripropylene glycol divinyl ether, tetrapropylene glycol monovinyl ether, tetrapropylene glycol divinyl ether, pentapropylene glycol monovinyl ether, pentapropylene glycol divinyl ether, oligopropyleneglycol monovinyl ether, oligopropyleneglycol divinyl ether, polypropylene glycol monovinyl ether, polypropylene glycol divinyl ether, isosorbide divinyl ether, oxanorbornene divinyl ether, phenyl vinyl ether, n-butyl vinyl ether, isobutyl vinyl ether, octyl vinyl ether, cyclohexyl vinyl ether, hydroquinone divinyl ether, 1,4-butanediol divinyl ether, cyclohexanedimethanol divinyl ether, trimethylolpropane divinyl ether, trimethylolpropane trivinyl ether, bisphenol A divinyl ether, bisphenol F divinyl ether, hydroxyoxanorbornane methanol divinyl ether, 1,4-cyclohexanediol divinyl ether, pentaerythritol trivinyl ether, pentaerythritol tetravinyl ether, dipentaerythritol pentavinyl ether, and dipentaerythritol hexavinyl ether.

In the hard coating agent, an epoxy compound is preferably used as the additional photocationically curable compound in combination with the polyorganosilsesquioxane of the present disclosure.

For the additional photoradically curable compound, a known or commonly used photoradically curable compound can be used and is not particularly limited. However, examples include a compound other than the polyorganosilsesquioxane of the present disclosure, the compound having one or more photoradically polymerizable groups, such as a (meth)acrylic group, a (meth)acryloxy group, a (meth)acrylamino group, a vinyl ether group, a vinylaryl group, or a vinyloxycarbonyl group per molecule. In the hard coating agent, one type of the additional photoradically curable compound may be used alone, or two or more types thereof may be used in combination.

Examples of compounds having one or more (meth)acrylic groups per molecule include 1-buten-3-one, 1-penten-3-one, 1-hexen-3-one, 4-phenyl-1-buten-3-one, 5-phenyl-1-penten-3-one, and derivatives thereof.

Compounds having one or more (meth)acryloxy groups per molecule include monomers or oligomers having one or more (meth)acryloxy groups per molecule.

Examples of the monomers having one or more (meth)acryloxy groups per molecule include methyl (meth)acrylate, ethyl (meth)acrylate, n-butyl (meth)acrylate, isobutyl (meth)acrylate, t-butyl (meth)acrylate, n-hexyl (meth)acrylate, 2-ethylhexyl (meth)acrylate, isodecyl (meth)acrylate, n-lauryl (meth)acrylate, n-stearyl (meth)acrylate, n-butoxyethyl (meth)acrylate, butoxy diethylene glycol (meth)acrylate, methoxy triethylene glycol (meth)acrylate, methoxy polyethylene glycol (meth)acrylate, cyclohexyl (meth)acrylate, tetrahydrofurfuryl (meth)acrylate, benzyl (meth)acrylate, phenoxyethyl (meth)acrylate, isobornyl (meth)acrylate, 2-hydroxyethyl (meth)acrylate, 2-hydroxypropyl (meth)acrylate, 2-hydroxybutyl (meth)acrylate, dimethylaminoethyl (meth)acrylate, diethylaminoethyl (meth)acrylate, acrylic acid, methacrylic acid, 2-(meth)acryloyloxyethyl succinic acid, 2-(meth)acryloyloxyethyl hexahydrophthalic acid, 2-(meth)acryloyloxyethyl-2-hydroxypropyl phthalate, glycidyl (meth)acrylate, 2-(meth)acryloyloxyethyl acid phosphate, ethylene glycol di(meth)acrylate, diethylene glycol di(meth)acrylate, triethylene glycol di(meth)acrylate, 1,4-butanediol di(meth)acrylate, neopentyl glycol di(meth)acrylate, 1,6-hexanediol di(meth)acrylate, 1,9-nonanediol di(meth)acrylate, 1,10-decanediol di(meth)acrylate, decane di(meth)acrylate, glycerin di(meth)acrylate, 2-hydroxy-3-(meth)acryloyloxypropyl (meth)acrylate, dimethylol tricyclodecane di(meth)acrylate, trifluoroethyl (meth)acrylate, perfluorooctylethyl (meth)acrylate, isoamyl (meth)acrylate, isomyristyl (meth)acrylate, γ-(meth)acryloyloxypropyltrimethoxysilane, 2-(meth)acryloyloxyethyl isocyanate, 1,1-bis(acryloyloxy)ethyl isocyanate, 2-(2-(meth)acryloyloxyethyloxy)ethyl isocyanate, 3-(meth)acryloyloxypropyltriethoxysilane, and derivatives thereof.

Examples of the oligomers having one or more (meth)acryloxy groups per molecule include urethane (meth)acrylate oligomers, epoxy (meth)acrylate oligomers, polyether (meth)acrylate oligomers, and polyester (meth)acrylate oligomers.

Examples of the urethane (meth)acrylate oligomers include polycarbonate-based urethane (meth)acrylate, polyester-based urethane (meth)acrylate, polyether-based urethane (meth)acrylate, and caprolactone-based urethane (meth)acrylate. The urethane (meth)acrylate oligomer can be obtained through a reaction between a (meth)acrylate monomer having a hydroxyl group, and an isocyanate compound obtained by reacting a polyol with diisocyanate. Examples of the polyol include polycarbonate diols, polyester polyols, polyether polyols, and polycaprolactone polyols.

The epoxy (meth)acrylate oligomer is obtained by, for example, an esterification reaction between acrylic acid and an oxirane ring of a low molecular weight bisphenol type epoxy resin or a novolac epoxy resin.

The polyether (meth)acrylate oligomer is obtained by producing a polyether oligomer having hydroxyl groups at both ends through a dehydration condensation reaction of a polyol, followed by subjecting the hydroxyl groups at both ends to esterification with acrylic acid.

The polyester (meth)acrylate oligomer is obtained, for example, by producing a polyester oligomer having hydroxyl groups at both ends through condensation of a polycarboxylic acid and a polyol, followed by subjecting the hydroxyl groups at both ends to esterification with acrylic acid.

The weight average molecular weight of the oligomer having one or more (meth)acryloxy groups per molecule is preferably 100000 or less and particularly preferably from 500 to 50000.

Examples of compounds having one or more (meth)acrylamino groups per molecule include 4-(meth)acrylmorpholine, N,N-dimethyl (meth)acrylamide, N,N-diethyl (meth)acrylamide, N-methyl (meth)acrylamide, N-ethyl (meth)acrylamide, N-propyl (meth)acrylamide, N-isopropyl (meth)acrylamide, N-butyl (meth)acrylamide, N-n-butoxymethyl (meth)acrylamide, N-hexyl (meth)acrylamide, N-octyl (meth)acrylamide, and derivatives thereof.

Examples of compounds having one or more vinyl ether groups per molecule include 3,3-bis(vinyloxymethyl) oxetane, 2-hydroxyethyl vinyl ether, 3-hydroxypropyl vinyl ether, 2-hydroxypropyl vinyl ether, 2-hydroxyisopropyl vinyl ether, 4-hydroxybutyl vinyl ether, 3-hydroxybutyl vinyl ether, 2-hydroxybutyl vinyl ether, 3-hydroxyisobutyl vinyl ether, 2-hydroxyisobutyl vinyl ether, 1-methyl-3-hydroxypropyl vinyl ether, 1-methyl-2-hydroxypropyl vinyl ether, 1-hydroxymethylpropyl vinyl ether, 4-hydroxycyclohexyl vinyl ether, 1,6-hexanediol monovinyl ether, 1,4-cyclohexanedimethanol monovinyl ether, 1,3-cyclohexanedimethanol monovinyl ether, 1,2-cyclohexanedimethanol monovinyl ether, p-xylene glycol monovinyl ether, m-xylene glycol monovinyl ether, o-xylene glycol monovinyl ether, diethylene glycol monovinyl ether, triethylene glycol monovinyl ether, tetraethylene glycol monovinyl ether, pentaethylene glycol monovinyl ether, oligoethylene glycol monovinyl ether, polyethylene glycol monovinyl ether, dipropylene glycol monovinyl ether, tripropylene glycol monovinyl ether, tetrapropylene glycol monovinyl ether, pentapropylene glycol monovinyl ether, oligopropylene glycol monovinyl ether, polypropylene glycol monovinyl ether, and derivatives thereof.

Examples of compounds having one or more vinylaryl groups per molecule include styrene, divinylbenzene, methoxystyrene, ethoxystyrene, hydroxystyrene, vinylnaphthalene, vinylanthracene, 4-vinylphenyl acetate, (4-vinylphenyl)dihydroxyborane, N-(4-vinylphenyl) maleimide, and derivatives thereof.

Examples of compounds having one or more vinyloxycarbonyl groups per molecule include isopropenyl formate, isopropenyl acetate, isopropenyl propionate, isopropenyl butyrate, isopropenyl isobutyrate, isopropenyl caproate, isopropenyl valerate, isopropenyl isovalerate, isopropenyl lactate, vinyl acetate, vinyl propionate, vinyl butyrate, vinyl caproate, vinyl caprylate, vinyl laurate, vinyl myristate, vinyl palmitate, vinyl stearate, vinyl cyclohexane carboxylate, vinyl pivalate, vinyl octylate, vinyl monochloroacetate, divinyl adipate, vinyl acrylate, vinyl methacrylate, vinyl crotonate, vinyl sorbate, vinyl benzoate, vinyl cinnamate, and derivatives thereof.

In the hard coating agent, one type of the additional active energy ray-curable compound may be used alone, or two or more types thereof may be used in combination.

In the case where the hard coating agent contains an additional active energy ray-curable compound, the content (blended amount) thereof is not particularly limited, but is preferably from 3 to 50 mass %, more preferably from 5 to 40 mass %, and even more preferably from 7 to 30 mass % per the total amount of the polyorganosilsesquioxane of the present disclosure and the additional active energy ray-curable compound (100 mass %; the total amount of the active energy ray-curable compounds). Adjusting the content of the additional active energy ray-curable compound to 50 mass % or less tends to further improve the scratch resistance and toughness of the cured product (coating film). Meanwhile, adjusting the content of the additional active energy ray-curable compound to 3 mass % or more may make it possible to impart a desired performance (e.g., fast curing properties or viscosity adjustment for the hard coating agent) to the hard coating agent or the cured product (coating film).

When the hard coating agent contains a vinyl ether compound (in particular, a vinyl ether compound having one or more hydroxyl groups per molecule), the content (blended amount) of the vinyl ether compound is not particularly limited, but is preferably from 0.01 to 10 mass %, more preferably from 0.05 to 9 mass %, and even more preferably from 1 to 8 mass %, relative to the total amount (100 mass %; the total amount of active energy ray-curable compounds) of the polyorganosilsesquioxane of the present disclosure and the additional active energy ray-curable compound. When the content of the vinyl ether compound is controlled to the aforementioned range, the surface hardness of the cured product (coating film) is further increased, and a cured product (coating film) having a very high surface hardness tends to be obtained even if the irradiation dose of the active energy rays (e.g., ultraviolet rays) is reduced. In particular, when the content of the vinyl ether compound having one or more hydroxyl groups per molecule is controlled to the aforementioned range, the surface hardness of the cured product (coating film) tends to become particularly high.

The hard coating agent preferably contains an antioxidant. When the hard coating agent contains an antioxidant, the cured product (coating film) tends to further improve.

For the antioxidant, a known or commonly used antioxidant can be used and is not particularly limited. However, examples include a phenol-based antioxidant (phenol-based compound), a hindered amine-based antioxidant (hindered amine-based compound), a phosphorous-based antioxidant (phosphorous-based compound), and a sulfur-based antioxidant (sulfur-based compound).

Examples of the phenol-based antioxidant include monophenols such as 2,6-di-t-butyl-p-cresol, butylated hydroxyanisole, 2,6-di-t-butyl-p-ethylphenol, and stearyl-β-(3,5-di-t-butyl-4-hydroxyphenyl) propionate; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol), and 3,9-bis[1,1-dimethyl-2-{β-(3-t-butyl-4-hydroxy-5-methylphenyl) propionyloxy}ethyl]2,4,8,10-tetraoxaspiro[5.5]undecane; and polymeric phenols such as 1,1,3-tris(2-methyl-4-hydroxy-5-t-butylphenyl) butane, 1,3,5-trimethyl-2,4,6-tris(3,5-di-t-butyl-4-hydroxybenzyl)benzene, tetrakis[methylene-3-(3′,5′-di-t-butyl-4′-hydroxyphenyl) propionate]methane, bis[3,3′-bis(4′-hydroxy-3′-t-butylphenyl) butyric acid]glycol ester, 1,3,5-tris(3′,5′-di-t-butyl-4′-hydroxybenzyl)-s-triazine-2,4,6-(1H,3H,5H)trione, and tocophenol.

Examples of the hindered amine-based antioxidant include bis(1,2,2,6,6-pentamethyl-4-piperidyl) [[3,5-bis(1,1-dimethylethyl)-4-hydroxyphenyl]methyl]butyl malonate, bis(1,2,2,6,6-pentamethyl-4-piperidyl) sebacate, methyl-1,2,2,6,6-pentamethyl-4-piperidyl sebacate, and 4-benzoyloxy-2,2,6,6-tetramethylpiperidine.

Examples of the phosphorus-based antioxidant include phosphites such as triphenyl phosphite, diphenylisodecyl phosphite, phenyldiisodecyl phosphite, tris(nonylphenyl) phosphite, diisodecylpentaerythritol phosphite, tris(2,4-di-t-butylphenyl) phosphite, cyclic neopentanetetraylbis(octadecyl) phosphite, cyclic neopentanetetraylbis(2,4-di-t-butylphenyl) phosphite, cyclic neopentanetetraylbis(2,4-di-t-butyl-4-methylphenyl) phosphite, and bis[2-t-butyl-6-methyl-4-{2-(octadecyloxycarbonyl)ethyl}phenyl]hydrogen phosphite; and oxaphosphaphenanthrene oxides such as 9,10-dihydro-9-oxa-10-phosphaphenanthrene-10-oxide, and 10-(3,5-di-t-butyl-4-hydroxybenzyl)-9,10-dihydro-9-oxa-10-phosphaphenanthrene-10-oxide.

Examples of the sulfur-based antioxidant include dodecanethiol, dilauryl-3,3′-thiodipropionate, dimyristyl-3,3′-thiodipropionate, and distearyl-3,3′-thiodipropionate.

Among these, the antioxidant is preferably a phenol-based antioxidant, a phosphorus-based antioxidant, or a sulfur-based antioxidant, and particularly preferably a phenol-based antioxidant. In the hard coating agent, one type of the antioxidant may be used alone, or two or more types thereof may be used in combination.

In the case where the hard coating agent contains an antioxidant, the content (blended amount) thereof is not particularly limited, but is preferably from 0.05 to 5 parts by mass and more preferably from 0.1 to 3 parts by mass per the total amount (100 parts by mass) of the active energy ray-curable compounds contained in the hard coating agent. When the content of the antioxidant is less than 0.05 parts by mass, the cured product (coating film) may be insufficient. Meanwhile, when the content of the antioxidant exceeds 5 parts by mass, the cured product (coating film) may become prone to coloration.

The hard coating agent preferably contains a compound having one or more thermally polymerizable functional groups and one or more photopolymerizable functional groups per molecule (hereinafter the compound may be referred to as “compound A”). In the case where the hard coating agent contains the compound A together with the polyorganosilsesquioxane of the present disclosure, the crosslink density can be effectively increased when a cured product is formed, and the cured product (coating film) is easily provided with high surface hardness and excellence.

The “thermally polymerizable functional group” in the compound A is not particularly limited as long as it is a functional group that imparts polymerizability by heat to the compound A. Examples of the functional group include a hydroxyl group, an epoxy group, an oxetanyl group, and a vinyl ether group. From the viewpoint of the surface hardness of the coating film of the present disclosure, a hydroxyl group or an epoxy group is preferred. In the case where the compound A has two or more thermally polymerizable functional groups, these thermally polymerizable functional groups may be the same or different.

The “photopolymerizable functional group” in the compound A is not particularly limited as long as it is a functional group that imparts polymerizability by light (e.g., ultraviolet rays) to the compound A. Examples of the functional group include a (meth)acryloyl group and a vinyl group. From the viewpoint of the surface hardness of the coating film of the present disclosure, a (meth)acryloyl group is preferred. In the case where the compound A has two or more photopolymerizable functional groups, these photopolymerizable functional groups may be the same or different.

The number of the thermally polymerizable functional groups contained in the compound A per molecule is not particularly limited as long as it is one or more. For example, the number is preferably from 1 to 5, more preferably from 1 to 3, and even more preferably 1 or 2. The number of the photopolymerizable functional groups contained in the compound A per molecule is not particularly limited as long as it is one or more. For example, the number is preferably from 1 to 5, more preferably from 1 to 3, and even more preferably 1 or 2.

The functional group equivalent of the thermally polymerizable functional group of the compound A is not particularly limited, but is preferably from 50 to 500, more preferably from 80 to 480, and even more preferably from 120 to 450. When the functional group equivalent is less than 50, the cured product (coating film) may be insufficient. Meanwhile, when the functional group equivalent is more than 500, the surface hardness of the cured product (coating film) may decrease. The functional group equivalent of the thermally polymerizable functional group of the compound A can be calculated by the following equation.

[Functional group equivalent of thermally polymerizable functional group]=[molecular weight of compound A]/[number of thermally polymerizable functional groups contained in compound A]

The functional group equivalent of the photopolymerizable functional group of the compound A is not particularly limited, but is preferably from 50 to 500, more preferably from 80 to 480, and even more preferably from 120 to 450. When the functional group equivalent is less than 50, the cured product (coating film) may be insufficient. Meanwhile, when the functional group equivalent is more than 500, the surface hardness of the cured product (coating film) may decrease. The functional group equivalent of the photopolymerizable functional group of the compound A can be calculated by the following equation.

[Functional group equivalent of photopolymerizable functional group]=[molecular weight of compound A]/[number of photopolymerizable functional groups contained in compound A]

Specific examples of the compound (A) include compounds having an epoxy group and or a hydroxyl group and a (meth)acryloyl group per molecule, such as 3,4-epoxycyclohexylmethyl (meth)acrylate, glycidyl (meth)acrylate, tripropylene glycol diglycidyl ether di(meth)acrylate (a compound produced by reacting (meth)acrylic acid with both epoxy groups of tripropylene glycol diglycidyl ether), tripropylene glycol diglycidyl ether half (meth)acrylate (a compound produced by reacting (meth)acrylic acid with one epoxy group of tripropylene glycol diglycidyl ether), bisphenol A epoxy di(meth)acrylate (a compound produced by reacting (meth)acrylic acid with both epoxy groups of bisphenol A diglycidyl ether), bisphenol A epoxy half (meth)acrylate (a compound produced by reacting (meth)acrylic acid or a derivative thereof with one epoxy group of bisphenol A diglycidyl ether), bisphenol F epoxy di(meth)acrylate, bisphenol F epoxy half (meth)acrylate, bisphenol S epoxy di(meth)acrylate, and bisphenol S epoxy half (meth)acrylate; compounds having an oxetanyl group and a (meth)acryloyl group per molecule, such as 3-oxetanylmethyl (meth)acrylate, 3-methyl-3-oxetanylmethyl (meth)acrylate, 3-ethyl-3-oxetanylmethyl (meth)acrylate, 3-butyl-3-oxetanylmethyl (meth)acrylate, and 3-hexyl-3-oxetanylmethyl (meth)acrylate; and compounds having a vinyl ether group and a (meth)acryloyl group per molecule, such as 2-vinyloxyethyl (meth)acrylate, 3-vinyloxypropyl (meth)acrylate, 1-methyl-2-vinyloxyethyl (meth)acrylate, 2-vinyloxypropyl (meth)acrylate, 4-vinyloxybutyl (meth)acrylate, 1-methyl-3-vinyloxypropyl (meth)acrylate, 1-vinyloxymethylpropyl (meth)acrylate, 2-methyl-3-vinyloxypropyl (meth)acrylate, 1,1-dimethyl-2-vinyloxyethyl (meth)acrylate, 3-vinyloxybutyl (meth)acrylate, 1-methyl-2-vinyloxypropyl (meth)acrylate, 2-vinyloxybutyl (meth)acrylate, 4-vinyloxycyclohexyl (meth)acrylate, 6-vinyloxyhexyl (meth)acrylate, 4-vinyloxymethylcyclohexylmethyl (meth)acrylate, 3-vinyloxymethylcyclohexylmethyl (meth)acrylate, 2-vinyloxycyclohexylmethyl (meth)acrylate, p-vinyloxymethylphenylmethyl (meth)acrylate, m-vinyloxymethylphenylmethyl (meth)acrylate, o-vinyloxymethylphenylmethyl (meth)acrylate, 2-(vinyloxyethoxy)ethyl (meth)acrylate, 2-(vinyloxyisopropoxy)ethyl (meth)acrylate, 2-(vinyloxyethoxy)propyl (meth)acrylate, 2-(vinyloxyethoxy)isopropyl (meth)acrylate, 2-(vinyloxyisopropoxy)propyl (meth)acrylate, 2-(vinyloxyisopropoxy)isopropyl (meth)acrylate, 2-(vinyloxyethoxyethoxy)ethyl (meth)acrylate, 2-(vinyloxyethoxyisopropoxy)ethyl (meth)acrylate, 2-(vinyloxyisopropoxyethoxy)ethyl (meth)acrylate, 2-(vinyloxyisopropoxyisopropoxy)ethyl (meth)acrylate, 2-(vinyloxyethoxyethoxy)propyl (meth)acrylate, 2-(vinyloxyethoxyisopropoxy)propyl (meth)acrylate, 2-(vinyloxyisopropoxyethoxy)propyl (meth)acrylate, 2-(vinyloxyisopropoxyisopropoxy)propyl (meth)acrylate, 2-(vinyloxyethoxyethoxy)isopropyl (meth)acrylate, 2-(vinyloxyethoxyisopropoxy)isopropyl (meth)acrylate, 2-(vinyloxyisopropoxyethoxy)isopropyl (meth)acrylate, 2-(vinyloxyisopropoxyisopropoxy)isopropyl (meth)acrylate, 2-(vinyloxyethoxyethoxyethoxy)ethyl (meth)acrylate, 2-(vinyloxyethoxyethoxyethoxyethoxy)ethyl (meth)acrylate, 2-(isopropenoxyethoxy)ethyl (meth)acrylate, 2-(isopropenoxyethoxyethoxy)ethyl (meth)acrylate, 2-(isopropenoxyethoxyethoxyethoxy)ethyl (meth)acrylate, 2-(isopropenoxyethoxyethoxyethoxyethoxy)ethyl (meth)acrylate, polyethylene glycol monovinyl ether (meth)acrylate, and polypropylene glycol monovinyl ether (meth)acrylate.

From the viewpoint of the surface hardness of the cured product (coating film), the compound A is preferably a compound having, per molecule, an epoxy group and/or a hydroxyl group as a thermally polymerizable functional group and a (meth)acryloyl group as a photopolymerizable functional group, and specifically preferably 3,4-epoxycyclohexylmethyl (meth)acrylate, glycidyl (meth)acrylate, tripropylene glycol diglycidyl ether half (meth)acrylate, bisphenol A epoxy half (meth)acrylate, bisphenol F epoxy half (meth)acrylate, bisphenol S epoxy half (meth)acrylate, or the like.

In the hard coating agent, one type of the compound A may be used alone, or two or more types thereof may be used in combination. The compound A can be produced by a known method and is obtained, for example, by a method of reacting some of the thermally polymerizable functional groups of a compound having two or more thermally polymerizable functional groups (e.g., an epoxy group and a hydroxyl group) per molecule with a carboxylic acid (e.g., such as acrylic acid or methacrylic acid) having a photopolymerizable functional group or its derivative.

The content (blended amount) of the compound A in the hard coating agent is not particularly limited but, as a solid content, is preferably from 1.0 to 100 parts by mass, more preferably from 1.3 to 75 parts by mass, and even more preferably from 1.5 to 50 parts by mass per the total amount of 100 parts by weight of the polyorganosilsesquioxane of the present disclosure and an additional active energy ray-curable compound (the total amount of the active energy ray-curable compounds). Adjusting the content of the compound A to 1 part by mass or more tends to further improve the cured product (coating film). Meanwhile, adjusting the content of the compound A to 100 parts by mass or less tends to be able to maintain the surface hardness of the cured product (coating film).

The hard coating agent preferably contains a fluorine-containing photopolymerizable compound. The fluorine-containing photopolymerizable compound is a compound (monomer, oligomer, polymer) having, in the molecule, a fluorine-containing group such as a fluoroaliphatic hydrocarbon skeleton and a photopolymerizable functional group. When the hard coating agent contains a fluorine-containing photopolymerizable compound along with the compound A and the polyorganosilsesquioxane of the present disclosure, the crosslink density of the coating film surface when the curable composition is formed into a cured product can be effectively increased, and properties of improving the appearance such as the smoothness of the surface of the cured product (coating film), and of improving the surface hardness, scratch resistance, and antifouling property are imparted. In particular, this effect is made remarkable by blending the fluorine-containing photopolymerizable compound along with the compound A in the hard coating agent.

Examples of the photopolymerizable functional group contained in the fluorine-containing photopolymerizable compound include the same “photopolymerizable functional groups” of the compound A described above, and from the viewpoint of the scratch resistance and antifouling property of the coating film according to an embodiment of the present disclosure, the photopolymerizable functional group is preferably a (meth)acryloyl group. When the fluorine-containing photopolymerizable compound has two or more photopolymerizable functional groups, these photopolymerizable functional groups may be the same or different.

The number of the photopolymerizable functional groups contained in the fluorine-containing photopolymerizable compound per molecule is not particularly limited as long as it is one or more. For example, the number is preferably from 1 to 5, and more preferably from 1 to 3.

The “fluorine-containing group” contained in the fluorine-containing photopolymerizable compound is not particularly limited as long as it has a fluorine atom, and examples include those having a fluoroaliphatic hydrocarbon skeleton. Examples of the fluoroaliphatic hydrocarbon skeleton can include fluoro C₁-10 alkanes such as fluoromethane, fluoroethane, fluoropropane, fluoroisopropane, fluorobutane, fluoroisobutane, fluoro t-butane, fluoropentane, and fluorohexane.

Any of these fluoroaliphatic hydrocarbon skeletons may be used so long as at least some of the hydrogen atoms therein are substituted by fluorine atoms, but from the viewpoint of being able to improve the scratch resistance, sliding properties, and antifouling property of the coating film, a perfluoroaliphatic hydrocarbon skeleton in which all of the hydrogen atoms are substituted by the fluorine atoms is preferable.

Furthermore, the fluoroaliphatic hydrocarbon skeleton may form a polyfluoroalkylene ether skeleton of repeating units via an ether bond. The fluoroaliphatic hydrocarbon group as the repeating unit may be at least one selected from the group consisting of fluoro C₁₋₄ alkylene groups such as fluoromethylene, fluoroethylene, fluoropropylene, and fluoroisopropylene. The number of repetitions of the polyfluoroalkylene ether units (degree of polymerization) is, for example, 10 to 3000, preferably 30 to 1000, more preferably 50 to 500.

The fluorine-containing photopolymerizable compound may have a silicone-containing group in addition to the “photopolymerizable functional group” and “fluorine-containing group” described above. When the fluorine-containing photopolymerizable compound further includes a silicone-containing group, affinity with the polyorganosilsesquioxane of the present disclosure is improved, and the surface hardness, scratch resistance, and antifouling property of the cured product (coating film) tend to be further improved. The silicone-containing group is a group having a polyorganosiloxane skeleton, and any polyorganosiloxane may be used so long as it is formed from an M unit, a D unit, a T unit, or a Q unit. However, typically, a polyorganosiloxane formed from a D unit is preferably used. Typical organic groups used in the polyorganosiloxane include a C₁₋₄ alkyl group and an aryl group, and a methyl group and a phenyl group (in particular, a methyl group) are commonly used. The number of repetitions of the siloxane units (degree of polymerization) is, for example, 2 to 3000, preferably 3 to 2000, more preferably 5 to 1000.

One type of the fluorine-containing photopolymerizable compound may be used alone, or two or more types thereof may be used in combination.

The content (blended amount) of the fluorine-containing photopolymerizable compound in the hard coating agent is not particularly limited but, as a solid content, is, for example, from 0.01 to 15 parts by mass, preferably from 0.02 to 10 parts by mass, more preferably from 0.03 to 5 parts by mass, and even more preferably from 0.04 to 3 parts by mass per the total amount of 100 parts by weight of the polyorganosilsesquioxane of the present disclosure and an additional active energy ray-curable compound (the total amount of the active energy ray-curable compounds). Adjusting the content of the fluorine-containing photopolymerizable compound to 0.01 parts by mass or more tends to further improve the scratch resistance, antifouling property of the cured product (coating film).

The hard coating agent preferably contains a surface conditioner. For the surface conditioner, a known or commonly used compound to be added for the purpose of antifoaming, leveling, anti-popping, or the like can be used.

For the antifoaming agent, leveling agent, or anti-popping agent, for example, an aqueous or non-aqueous compound composed of a main component selected from polymer main components, such as butadiene, acryl, and olefin, or silicone-based main components, such as silicone and fluorine-modified silicone, can be used.

The content (blended amount) of the surface conditioner in the hard coating agent is not particularly limited but, as a solid content, is, for example, from 0.01 to 15 parts by mass, preferably from 0.05 to 10 parts by mass, more preferably from 0.1 to 5 parts by mass, and even more preferably from 0.2 to 3 parts by mass per the total amount of 100 parts by weight of the polyorganosilsesquioxane of the present disclosure and an additional active energy ray-curable compound (the total amount of the active energy ray-curable compounds). Adjusting the content of the surface conditioner to 0.01 parts by mass or more tends to further improve the leveling properties of the cured product (coating film).

Preferably, the hard coating agent may further contain a solvent. The solvent is not particularly limited as long as it can dissolve the polyorganosilsesquioxane of the present disclosure and an additive used as necessary and does not inhibit polymerization.

The solvent that is used is preferably one that can impart fluidity suitable for coating onto the hard coat layer and that can be easily removed by heating at a temperature at which the progression of polymerization can be suppressed. It is preferable to use one type or two or more types of solvent having a boiling point (at 1 atm) of 170° C. or lower (e.g., an aromatic solvent such as toluene, xylene, or mesitylene, an ester such as butyl acetate, a ketone such as methyl isobutyl ketone or cyclohexanone, or an ether such as propylene glycol monomethyl ether or propylene glycol monomethyl ether acetate).

From the viewpoint of excellent coating properties, the solvent is preferably used in such a range that the concentration of the non-volatile content contained in the hard coating agent is, for example, about from 5 to 100 mass %, preferably from 10 to 80 mass %, and particularly preferably from 20 to 70 mass %. However, the addition amount is not limited to the range described above, and an optimal addition amount should be selected to adjust to a viscosity at which an appropriate film thickness can be achieved. That is, using an excess amount of the solvent may reduce the viscosity of the hard coating agent and tend to make it difficult to form a coating film having an appropriate film thickness. Meanwhile, using too small an amount of the solvent may increase the viscosity of the hard coating agent excessively and tend to make it difficult to uniformly apply the hard coating agent to an alternative glass substrate.

The hard coating agent may further contain a commonly used additive as an additional optional component, including an inorganic filler, such as precipitated silica, wet silica, fumed silica, calcined silica, titanium oxide, alumina, glass, quartz, aluminosilicic acid, iron oxide, zinc oxide, calcium carbonate, carbon black, silicon carbide, silicon nitride, or boron nitride; an inorganic filler obtained by treating such a filler with an organosilicon compound, such as an organohalosilane, organoalkoxysilane, or organosilazane; an organic resin fine powder, such as a silicone resin, an epoxy resin, or a fluororesin; a filler, such as a conductive metal powder of silver, copper, or the like, a curing aid, a stabilizer (such as a light-resistant stabilizer, a heat stabilizer, or a heavy metal inactivator), an ultraviolet absorber (a triazine-based ultraviolet absorber, a benzotriazole-based ultraviolet absorber, a benzophenone-based ultraviolet absorber, an oxybenzophenone-based ultraviolet absorber, a salicylic acid ester-based ultraviolet absorber, or a cyanoacrylate-based ultraviolet absorber), a flame retardant (such as a phosphorus-based flame retardant, a halogen-based flame retardant, or an inorganic flame retardant), a flame retardant aid, a reinforcing material (such as an additional filler), a nucleating agent, a coupling agent (such as a silane coupling agent), a lubricant, a wax, a plasticizer, a release agent, an impact modifier, a hue modifier, a transparentizing agent, a rheology modifier (such as a fluidity modifier), a workability modifier, a colorant (such as a dye or a pigment), an antistatic agent, a dispersant, a surface modifier (such as a slipping agent), a matting agent, an antifoaming agent, a foam inhibitor, a defoamer, an antibacterial agent, a preservative, a viscosity modifier, a thickener, a photosensitizer, or a foaming agent. One type of the additive may be used alone, or two or more thereof may be used in combination.

The hard coating agent can be prepared by stirring and mixing the components described above at room temperature or with heating as necessary although the preparation is not particularly limited. For the hard coating agent, a one-component composition, which is prepared by mixing components in advance and used as is, can be used, or alternatively, a multi-component (e.g., two-component) composition, which constitutes two or more components stored separately and is prepared by mixing the components at a given ratio before use, can be used.

The hard coating agent is preferably a liquid at normal temperature (about 25° C.) although this is not particularly limited. More specifically, a liquid in which the hard coating agent is diluted in 20% of a solvent [in particular, a hard coating agent solution with a proportion of methyl isobutyl ketone of 20 mass %] has a viscosity at 25° C. of preferably from 300 to 20000 mPa·s, more preferably from 500 to 10000 mPa·s, and even more preferably from 1000 to 8000 mPa·s. When the viscosity described above is 300 mPa·s or more, the cured product (coating film) tends to further improve. Meanwhile, adjusting the viscosity to 20000 mPa·s or less facilitates the preparation and handling of the hard coating agent and tends to less likely to leave residual bubbles in the cured product (coating film). The viscosity of the hard coating agent is measured using a viscometer (trade name “MCR301”, available from Anton Paar GmbH) under conditions of a swing angle of 5%, a frequency of 0.1 to 100 (1/s), and a temperature of 25° C.

As a method of applying and curing the hard coat layer, an ordinary coating method can be used. For example, a known method such as dipping, roll coating, gravure coating, reverse coating, air knife coating, comma coating, die coating, screen printing, spray coating, gravure offset method, and organic vapor deposition can be used. An example of the curing method is irradiation with light using, for example, a mercury lamp, a xenon lamp, a carbon arc lamp, a metal halide lamp, sunlight, an electron beam source, a laser light source, or an LED light source. When the hard coat layer is cured by irradiation with ultraviolet rays, for example, the cumulative irradiation dose is preferably approximately from 1 to 5000 mJ/cm².

The specific curing conditions are not particularly limited, but for example, the hard coating agent can be first heat-treated (prebaked) at preferably 60° C. or higher, more preferably 120° C. or higher, and even more preferably 150° C. or higher for preferably 10 seconds or more, more preferably 30 seconds or more, and even more preferably 60 seconds or more, then irradiated with ultraviolet rays (irradiation conditions (irradiation dose): preferably of 300 mJ/cm² or more and an irradiation intensity of 100 mW/cm² or more), and finally cured by heat treatment (aging) at preferably 120° C. or higher for preferably 0.5 hours or more. However, the curing conditions are not limited to the above range, and the pre-baking temperature and time, and the aging temperature and time can be selected, as appropriate, depending on the solvent that is used, and the ultraviolet irradiation conditions can be selected, as appropriate, depending on the curing agent that is used.

The hard coating agent can form a hard coat layer having high scratch resistance, surface hardness, and toughness by application and curing as described above. The thus-produced laminate has excellent adhesion and can improve the surface hardness of the hard coat layer.

The thickness of the hard coat layer is preferably 25 μm or more, and more preferably 30 μm or more. When the thickness of the hard coat layer is 25 μm or more, impact resistance is exhibited, and it becomes easy to prevent generation of a crack in a pen drop test. The upper limit is not particularly limited, but is preferably 70 μm or less, and more preferably 60 μm or less. Bending resistance is easily exhibited by adjusting the thickness of the hard coat layer to 70 μm or less. When the hard coat layer is formed on both surfaces of the glass substrate, the thickness of at least one of the hard coat layers is preferably 25 μm or more, and more preferably 30 μm or more. From the viewpoint of exhibiting bending resistance, the thickness of each of the hard coat layers is preferably 70 μm or less, and more preferably 60 μm or less.

### Display Device

An embodiment of the present disclosure is a display device including the laminate. In the device described above, the laminate is disposed such that, for example, the hard coat layer configures the surface on the viewing side. The display device is not particularly limited, and examples thereof include display devices, such as an organic EL display device, an inorganic EL display device, and a liquid crystal display device. In the display device, since the surface of the hard coat layer has sufficient indentation hardness, scratches are less likely to occur on the surface, and the touch properties are excellent. The display device can also be used as a flexible display that can be bent, rolled, or the like.

Each embodiment disclosed in the present specification can be combined with any other feature disclosed in the present specification. The configurations, combinations thereof, and the like in each embodiment are examples, and various additions, omissions, and other changes of the configurations may be made, as appropriate, without departing from the spirit of the present disclosure. The present disclosure is not limited by the embodiments and is limited only by the claims.

### EXAMPLES

An embodiment of the present disclosure will be described in more detail below based on Examples.

### Production Example 1

### Production of Polyorganosilsesquioxane

277.2 mmol (68.30 g) of 2-(3,4-epoxycyclohexyl)ethyltrimethoxysilane, 3.0 mmol (0.56 g) of phenyltrimethoxysilane, and 275.4 g of acetone were added to a 1000 milliliter flask (reaction vessel) equipped with a thermometer, a stirrer, a reflux condenser, and a nitrogen inlet tube under a nitrogen stream, and the temperature was raised to 50° C. To the thus-prepared mixture was added 7.74 g of 5% aqueous potassium carbonate solution (2.8 mmol as potassium carbonate) over 5 minutes, after which 2800.0 mmol (50.40 g) of water was added over 20 minutes. No significant temperature increase occurred during the addition. Subsequently, a polycondensation reaction was performed under a nitrogen stream for 5 hours while the temperature was maintained at 50° C.

Thereafter, the reaction solution was cooled, and simultaneously, 137.70 g of methyl isobutyl ketone and 100.60 g of 5% salt water were added thereto. The solution was transferred to a 1 L separating funnel, and then 137.70 g of methyl isobutyl ketone was again added, and water washing was performed. After the liquid separation, the water layer was removed, and the lower layer liquid was washed with water until the lower layer liquid became neutral. The upper layer liquid was then fractioned, after which the solvent was distilled off from the upper layer liquid under conditions of 1 mmHg and 50° C., to thereby produce 75.18 g of a colorless, transparent liquid product (an epoxy group-containing low molecular weight polyorganosilsesquioxane: SQ1) containing 23 mass % of methyl isobutyl ketone.

The product was analyzed, and the product was found to have a number average molecular weight of 2235 and a molecular weight dispersity of 1.54. The ratio [T3 form/T2 form] of T2 forms and T3 forms calculated from the ²⁹Si-NMR spectrum of the product was 11.9. The confirmation was performed through ¹H-NMR and ²⁹Si-NMR of the resulting epoxy group-containing low molecular weight polyorganosilsesquioxane.

The molecular weight of the product was measured using a pump: Shimadzu LC-20AD, a detector: Shodex RI-504, columns: Shodex GPC KF-602 and KF-603, a guard column: Shodex GPC KF-G, a solvent: THE, and a measurement condition: 40° C. The ratio [T3 form/T2 form] of T2 forms and T3 forms in the product was measured through ²⁹Si-NMR spectrum measurements using JEOL ECA500 (500 MHz).

### Preparation of Hard Coating Agent

Materials were mixed with the epoxy group-containing low molecular weight polyorganosilsesquioxane (SQ1) in the constituent proportions shown in Table 1, to thereby prepare a hard coating agent.

TABLE 1

| | Material | Solid content | Constituent |
|---|---|---|---|
| | Name | proportion % | proportion % |
| Curable compound | SQ1 | 77 | 57.3 |
| | 200PA-E5 | 100 | 1.3 |
| | Epolite 1600 | 100 | 5.0 |
| Radical polymerization | Omnirad 127 | 100 | 0.1 |
| initiator | | | |
| Cationic | CPI-310FG | 100 | 0.3 |
| polymerization | | | |
| initiator | | | |
| Antioxidant | ADK STAB | 100 | 0.1 |
| | AO-20 | | |
| Surface conditioner | KY1203 | 20 | 0.4 |
| Leveling agent | Ftergent 602A | 50 | 0.05 |
| Solvent | MIBK | — | 3.65 |
| | MEK | — | 31.8 |

Components shown in Table 1 are described in detail below.
200PA-E5: trade name “Epoxy Ester 200PA-E5”, available from Kyoeisha Chemical Co., Ltd. (compound having one or more thermally polymerizable functional groups and one or more photopolymerizable functional groups per molecule)
Epolight 1600: trade name “Epolight 1600”, available from Kyoeisha Chemical Co., Ltd. (additional photocationically curable compound)
Omnirad 127: trade name “Omnirad 127”, available from IGM Resins B.V. (photoradical polymerization initiator)
CPI-310FG: trade name “CPI-310FG”, available from San-Apro Ltd. (photocationic polymerization initiator)
ADK STAB AO-02: trade name “ADK STAB AO-02”, available from ADEKA Corporation (antioxidant)
KY1203: trade name “KY1203”, a compound containing a radical polymerizable group and fluorine, available from Shin-Etsu Chemical Co., Ltd. (surface conditioner)
Ftergent 602A: trade name “Ftergent 602A”, a fluorine-based surfactant containing a radical polymerizable group and a branched fluoroaliphatic hydrocarbon group, available from Neos Corporation (leveling agent)
MIBK: Methyl isobutyl ketone (solvent)
MEK: Methyl ethyl ketone (solvent)

### Examples 1 to 3 and Comparative Examples 1 to 2

Wire bars #12, 24, 34, 44, and 60 were respectively used to apply the hard coating agent onto UTG (available from SCHOTT, thickness: 70 μm, minimum bending diameter at which no crack is generated: 4 mm Φ) in respective amounts so as to achieve thicknesses of 10 μm, 20 μm, 30 μm, 40 μm, and 55 μm after curing of the hard coating agent, after which the coated UTG was left in an oven at 80° C. for 1 minute and then in an oven at 120° C. for 2 minutes. Next, ultraviolet rays were applied at an illuminance of 300 mJ/cm² using a high-pressure mercury lamp, to thereby form a hard coat layer. Subsequently, the resulting products were left in an oven at 120° C. for 60 minutes, to thereby produce laminates of Examples 1 to 3 and Comparative Examples 1 to 2.

### Comparative Example 3

A UTG without the hard coat layer was used for Comparative Example 3.

TABLE 2

| | | Solid content | Constituent |
|---|---|---|---|
| | Material Name | proportion % | proportion % |
| Curable compound | H-575 | 100 | 79.2 |
| Radical | Omnirad 184 | 100 | 1.0 |
| polymerization | | | |
| initiator | | | |
| Solvent | Toluene | — | 19.8 |

### Comparative Example 4

Urethane acrylate (trade name “H-575”, available from Negami Chemical Industrial Co., Ltd.), a radical polymerization initiator (trade name “Omnirad184”, available from IGM Resins B. V.), and toluene as a solvent were used instead of the aforementioned hard coating agent, and materials were blended in the constituent proportions shown in Table 2, to prepare a hard coating liquid. The wire bar #44 was used to apply the hard coating liquid in an amount so as to achieve a thickness of 30 μm after curing. Then, the resulting product was left in an oven at 120° C. for 3 minutes and then irradiated with ultraviolet rays at an illuminance of 500 mJ/cm² using a high-pressure mercury lamp, to produce a laminate of Comparative Example 4.

### Evaluation

The laminates produced in the Examples and Comparative Examples were subjected to the following evaluations. The results are shown in Table 3.

### (1) Bending Resistance

For the laminates of Examples 1 to 3 and Comparative Examples 1 to 4, a cylindrical mandrel bending tester (trade name “bending tester (cylindrical mandrel method)”, available from TP Giken Co., Ltd.) and a cylindrical mandrel method in accordance with JIS K 5600 May 1 were used to examine the bending resistance as follows (the used tester was equipped with 12 replaceable mandrels having mandrel diameters of 2 mm Φ, 3 mm Φ, 4 mm Φ, 5 mm Φ, 6 mm Φ, 8 mm Φ, 10 mm Φ, 12 mm Φ, 16 mm Φ, 20 mm Φ, 25 mm Φ, and 32 mm Φ).

In a bending test by the cylindrical mandrel method in which a test piece (15 mm×150 mm) cut out of the laminate was bent with the hard coat layer side inward, the minimum bending diameter (mm Φ) at which the test piece did not crack was examined. In the bending test, the laminate to be tested is subjected to 180° bending deformation around the mandrel along the circumferential surface of the mandrel, which is a core rod having a predetermined diameter, in a manner that the hard coat layer is positioned inward with respect to the glass substrate.

### (2) Indentation Hardness

The following test was performed using an indentation hardness measuring instrument (trade name “ELONIX Inc. ENT-1100a”, available from ELONIX Inc.). Each of the laminates produced in Examples 1 to 3 and Comparative Examples 1 to 4 was cut into a size of approximately 4 mm×4 mm that allowed the laminate to be placed on a test bench, and an instantaneous adhesive (trade name “Aron Alpha Fast-Acting Multi-Purpose”, available from Toagosei Co., Ltd.) was applied to a measurement pedestal and the cut laminate was fixed thereon such that the hard coat layer-formed surface was the outermost surface. The indentation load was adjusted to 50 μN and the measurement was performed. An average value of measurement results at 10 points was taken as the indentation hardness (N/mm²).

### (3) Impact Resistance (Pen Drop Test)

Each of the laminates produced in Examples 1 to 3 and Comparative Examples 1 to 4 was placed on a soda glass having a thickness of 4 mm such that the hard coat layer-formed surface was the upper surface, and a pen tip was vertically dropped onto the sample surface from a position where a distance from the pen tip to the surface of the laminate opposite to the soda glass was 30 mm. When a crack was generated on the sample surface, the sample was evaluated as “Fail”, whereas when no crack was generated, the sample was evaluated as “Pass”. The pen used was a ballpoint pen product number E-ORMJ20EGBLK (size: 13.7 mm, weight: 5.7 g, pen tip: 1.0 mm Φ) available from BIC Corporation.

### (4) Haze

The haze value (%) of each of the laminates of Examples 1 to 3 and Comparative Examples 1 to 4 was measured using a haze measuring instrument (trade name “NDH-5000W”, available from Nippon Denshoku Industries Co., Ltd.). This measurement was implemented in accordance with JIS K7136.

### (5) Total Light Transmittance

The total light transmittance (%) of each of the laminates of Examples 1 to 3 and Comparative Examples 1 to 4 was measured using a total light transmittance measuring instrument (trade name “NDH-5000W”, available from Nippon Denshoku Industries Co., Ltd.). This measurement was implemented in accordance with JIS K7105.

TABLE 3

| | HC | | Total light | Bending | Indentation | 30 mm pen |
|---|---|---|---|---|---|---|
| | Thickness | Haze | transmittance | resistance | hardness | drop impact |
| | (μm) | (%) | (%) | (mm Φ) | (N/mm²) | resistance |
| Comparative | 10 | 0.20 | 91.94 | 6 | 1335 | Fail |
| Example 1 | | | | | | |
| Comparative | 20 | 0.22 | 91.72 | 6 | 1432 | Fail |
| Example 2 | | | | | | |
| Example 1 | 30 | 0.45 | 91.48 | 6 | 1244 | Pass |
| Example 2 | 40 | 0.37 | 91.51 | 8 | 1478 | Pass |
| Example 3 | 55 | 0.60 | 91.18 | 10 | 1482 | Pass |
| Comparative | — | 0.21 | 91.98 | 4 | 6103 | Fail |
| Example 3 | | | | | | |
| Comparative | 30 | 0.71 | 91.79 | 6 | 815 | Fail |
| Example 4 | | | | | | |

In the laminates of Examples 1 to 3, it was confirmed that the minimum bending diameters at which no crack was generated in the mandrel test were 10 mm or less, that the indentation strengths were 850 N/mm² or more, that no crack was generated in the laminates in the pen drop test, and that the laminates were excellent in impact resistance, surface hardness, and bending resistance. In contrast, in the laminates of Comparative Examples 1 to 3, cracks were generated in the pen drop test, which indicated poor impact resistance. In the laminate of Comparative Example 4, the indentation hardness was smaller than 850 N/mm², and cracks were generated in the pen drop test, which indicated poor impact resistance and surface hardness.

Hereinafter, variations of the invention according to the present disclosure will be described.

### [Appendix 1]

A laminate including a glass substrate and a hard coat layer laminated on at least one surface of the glass substrate, wherein
the glass substrate has a thickness of from 1 to 100 μm;
the laminate has an indentation hardness of 850 N/mm² or more when the hard coat layer is an outermost surface;
no crack is generated when a pen is dropped to the laminate from a height of 30 mm; and
the laminate has a minimum bending diameter at which no crack is generated of 10 mm Φ or less when the laminate is bent with the hard coat layer facing inward.

### [Appendix 2]

The laminate according to appendix 1, wherein the laminate has a haze value of 1% or less.

### [Appendix 3]

The laminate according to appendix 1 or 2, wherein the laminate has a total light transmittance of 85% or more.

### [Appendix 4]

The laminate according to any one of appendices 1 to 3, wherein the hard coat layer has a thickness of 25 μm or more.

### [Appendix 5]

The laminate according to any one of appendices 1 to 4, wherein the hard coat layer is a cured product of a curable composition containing one or more curable compounds, and at least one of the curable compounds is a polyorganosilsesquioxane.

### [Appendix 6]

The laminate according to any one of appendices 1 to 5, wherein the glass substrate has a minimum bending diameter at which no crack is generated of 10 mm Φ or less when the glass substrate is bent.

### [Appendix 7]

An image display device including the laminate described in any one of appendices 1 to 6.

1. A laminate comprising a glass substrate and a hard coat layer laminated on at least one surface of the glass substrate, wherein
the glass substrate has a thickness of from 1 to 100 μm;
the laminate has an indentation hardness of 850 N/mm² or more when the hard coat layer is an outermost surface;
no crack is generated when a pen is dropped to the laminate from a height of 30 mm; and
the laminate has a minimum bending diameter at which no crack is generated of 10 mm Φ or less when the laminate is bent with the hard coat layer facing inward.

2. The laminate according to claim 1, wherein the laminate has a haze value of 1% or less.

3. The laminate according to claim 1, wherein the laminate has a total light transmittance of 85% or more.

4. The laminate according to claim 1, wherein the hard coat layer has a thickness of 25 μm or more.

5. The laminate according to claim 1, wherein the hard coat layer is a cured product of a curable composition containing one or more curable compounds, and at least one of the curable compounds is a polyorganosilsesquioxane.

6. The laminate according to claim 1, wherein the glass substrate has a minimum bending diameter at which no crack is generated of 10 mm Φ of less when the glass substrate is bent.

7. An image display device comprising the laminate described in claim 1.
